(19) United States
(12) Patent Application Publication
(10) Pub. No.: US 2025/0210514 A1
(43) Pub. Date: Jun. 26, 2025

(54) SEMICONDUCTOR MODULE

(71) Applicant: RESEARCH ASSOCIATION FOR ADVANCED SYSTEMS, Tokyo (JP)

(72) Inventors: Tadahiro KURODA, Toyko (JP); Masaya KAWANO, Tokyo (JP)

(21) Appl. No.: 19/076,417

(22) Filed: Mar. 11, 2025

Related U.S. Application Data
(63) Continuation of application No. PCT/JP2023/026387, filed on Jul. 19, 2023.

(30) Foreign Application Priority Data
Sep. 12, 2022 (JP) 2022-144892

(51) Int. Cl. H01L 23/522; H01L 23/00; H01L 25/18; H10B 80/00

(52) U.S. Cl. CPC H01L 23/5227; H01L 25/18; H01L 24/08; H01L 24/32; H01L 2224/08137; H01L 2224/32145; H10B 80/00

(57) ABSTRACT

The semiconductor module includes a semiconductor chip including a first surface parallel to a first direction and a second direction intersecting the first direction, and a second surface parallel to the first surface, and a memory cube including a plurality of memory chips stacked in the first direction and arranged on the second surface. Each of the plurality of memory chips includes a first inductor arranged in a third direction perpendicular to the first direction and the second direction. The semiconductor chip includes a second inductor arranged parallel to the second surface. The first inductor includes a first side and a second side extending in the third direction. The distance between the first side and the second side cut parallel to the second surface becomes shorter as the distance from the second surface increases in the third direction. The first inductor and the second inductor are capable of contactless communication.

### CROSS-REFERENCE TO RELATED APPLICATIONS

This application is a Continuation of International Patent Application No. PCT/JP2023/026387, filed on Jul. 19, 2023, which claims the benefit of priority to Japanese Patent Application No. 2022-144892, filed on Sep. 12, 2022, the entire contents of which are incorporated herein by reference.

### FIELD

An embodiment of the present invention relates to a semiconductor module and a method for manufacturing the same.

### BACKGROUND

In recent years, the power consumption of electronic computers such as data centers has rapidly increased. For example, the electronic computer includes a plurality of logic chips and a plurality of memory chips electrically connected to the plurality of logic chips. For example, the logic chip is an IC (Integrated Circuit) chip on which a logic circuit is mounted, and the memory chip is a semiconductor chip on which a memory circuit is mounted. For example, data communication in an electronic computer is performed between the logic chip and the memory chip. For example, in order to reduce the power consumption of the electronic computer, it is an effective solution to reduce the distance between the logic chip and the memory chip by three-dimensionally mounting the logic chip and the memory chip by stacking them.

A semiconductor module having a structure in which a plurality of memory chips is stacked (horizontally stacked memory cube) is vertically mounted on a substrate or logic chip so that the plurality of memory chips is perpendicular to the substrate or logic chip is known as an example of a high-density three-dimensional mounting method. For example, the horizontally stacked memory cube and the substrate or logic chip are electrically connected using a TSV or micro bump. Furthermore, for example, a vertically stacked memory cube is known in which the memory chips are stacked vertically using the TSV (Through-Silicon Via, silicon through electrode) or micro bump in order to reduce the power consumption of the electronic computer. Furthermore, for example, a technique for contactless communication between two chips is known.

### SUMMARY

A semiconductor module includes: a semiconductor chip including a first surface parallel to a first direction and a second direction intersecting the first direction, and a second surface parallel to the first surface; and a memory cube including a plurality of memory chips stacked in the first direction and arranged on the second surface, wherein each of the plurality of memory chips includes a first inductor arranged in a third direction perpendicular to the first direction and the second direction, the semiconductor chip includes a second inductor arranged parallel to the second surface, the first inductor includes a first side and a second side extending in the third direction in a front view, the distance between the first side and the second side cut parallel to the second surface becomes shorter as the distance from the second surface increases in the third direction, and the first inductor and the second inductor are capable of contactless communication.

In a front view, the first inductor has a first portion including the first side extending in the third direction and including a finite first width in the second direction, a second portion including the second side extending in the third direction and including a finite second width in the second direction, and a third portion close to the second surface, including one straight side parallel to the second surface, extending in the second direction, including a length parallel to the second direction and including a finite third width in the third direction, and the third width may be wider than the first width and the second width.

In a plan view, the shape of a region formed by lines extending the first side and the second side in the third direction and the second direction, respectively, and a side extending one of the straight sides in the second direction, may be triangular.

The third width is different for each of the plurality of memory chips, and the distance between one of the straight sides and the second surface may be substantially the same.

The memory chip includes a plurality of the first inductors, the second inductor includes one straight side, the one straight side of the first inductor and the one straight side of the second inductor are close to each other, and the length parallel to the second direction may be four times or more the distance between the one straight side of the first inductor and the one straight side of the second inductor.

The memory chip includes a plurality of the first inductors, the second inductor includes one straight side, the one straight side of the first inductor and the one straight side of the second inductor are adjacent to each other, and the distance between the first inductor and another first inductor adjacent to the first inductor may be equal to or greater than ¼ of the length parallel to the second direction.

At least a portion of the first inductor is arranged outside a seal ring arranged on the outer periphery of the memory chip, and the second inductor may be arranged inside a seal ring arranged on the outer periphery of the semiconductor chip.

The first inductor is composed of a wiring included in the memory chip and a side surface wiring arranged on a side surface of the memory cube, and the wiring may be different from the side surface wiring.

A semiconductor module includes: a memory cube including a plurality of stacked memory chips and including planarized first, second, third, and fourth side surfaces, wherein a wiring included in an inductor for communication is exposed on any one of the first, second, third, and fourth side surfaces, a power supply wiring and a ground wiring are exposed on at least one of any of the other side surfaces, and the wiring, the power supply wiring, and the ground wiring included in the inductor are included in wirings included in the memory chip.

The semiconductor module further includes: a semiconductor chip including a first side surface and a second side surface opposite the first side surface; and a heat sink, wherein any one of the first, second, third, and fourth side surfaces is arranged to face the second side surface, the heat sink is arranged on the side surface opposite the any one side of the surfaces, and at least one of the two side surfaces other than the any one of the side surfaces and the opposite side surface may be formed with a side surface power supply wiring electrically connected to the power supply wiring and a side surface ground wiring electrically connected to the ground wiring.

The side surface power supply wiring and the side surface ground wiring are arranged to extend to the second surface of the semiconductor chip, and may be connected to electrode pads included in the semiconductor chip.

Each of the plurality of memory chips includes a stacked configuration of a transistor layer including a substrate and a transistor and an inductor layer including the inductor, and the memory cube includes a stacked configuration in which the inductor layers of any two of the plurality of memory chips are bonded to each other, the transistor layers of two of the plurality of memory chips other than the any two memory chips are bonded to each other, and the plurality of memory chips is stacked.

The memory cube includes a first memory chip, a second memory chip stacked on the first memory chip, a third memory chip stacked on the second memory chip, a fourth memory chip stacked on the third memory chip, a fifth memory chip stacked on the fourth memory chip, and a sixth memory chip stacked on the fifth memory chip, the power supply wiring of each of the third memory chip to the sixth memory chip exposed on the at least one side surface is arranged as a first set of rows, the first set of rows is electrically connected by the side surface power supply wiring formed on the at least one side surface, the ground wiring of each of the first memory chip to the fourth memory chip exposed on the at least one side surface is arranged as a second set of rows, the second set of rows is electrically connected by a side surface ground wiring formed on the at least one side surface, and the first set of rows may be parallel to the second set of rows.

The side surface power supply wiring and the side surface ground wiring are arranged to extend from the side surface of the substrate to the second surface, and the side surface power supply wiring and the side surface ground wiring may include an L-shaped wiring that connects the memory cube and the semiconductor chip.

The semiconductor module further includes a side surface wiring electrically connected to a wiring included in the inductor, wherein the inductor may include the side surface wiring and a wiring included in the inductor.

Position information of the one straight side of all the inductors exposed on the any one of the side surfaces is mapped, the relative position between the one side of all the inductors and a predetermined position on the any one of the side surfaces is calculated and recorded, a center of gravity point at which the deviation is minimized between the one straight side of all the inductors and the one side of the inductor included in the semiconductor chip corresponding to each of the one side of all the inductors is calculated, and a set position for arranging the memory cube on the second surface of the semiconductor chip is offset to a position corresponding to the center of gravity point to arrange the memory cube on the second surface.

The semiconductor module may include, when arranging the memory cube on the second surface, measuring a position between the memory cube and the logic chip by communicating the inductor included in the memory chip with the inductor included in the semiconductor chip and measuring an induced current.

The memory cube includes a first memory chip, a second memory chip stacked on the first memory chip, a third memory chip stacked on the second memory chip, and a fourth memory chip stacked on the third memory chip, the third memory chip is thinner than the first memory chip, the second memory chip is thinner than the third memory chip, and the fourth memory chip may be thicker than the first memory chip.

### BRIEF DESCRIPTION OF DRAWINGS

FIG. 1 is a perspective view showing a configuration of a semiconductor module according to the first embodiment of the present invention.

FIG. 2 is a perspective view showing a plurality of inductors included in a logic chip and an inductor group included in a plurality of memory chips according to the first embodiment of the present invention.

FIG. 3A is a perspective view showing a configuration of the inductor on the logic chip and the inductor on the memory chip shown in FIG. 2.

FIG. 3B is a diagram showing the positional relationship between the logic chip and the inductor on the memory chip shown in FIG. 2.

FIG. 4 is a block diagram showing a configuration of a semiconductor module according to the first embodiment of the present invention.

FIG. 5 is a perspective view showing a configuration of a memory chip according to the first embodiment of the present invention.

FIG. 6 is a cross-sectional view showing a cross-sectional structure of a memory chip along a line A1-A2 shown in FIG. 5.

FIG. 7 is a block diagram showing a configuration of a memory chip according to the first embodiment of the present invention.

FIG. 8 is a plan view showing a configuration of an inductor group included in a memory chip according to the first embodiment of the present invention.

FIG. 9 is a perspective view showing a configuration of a logic chip according to the first embodiment of the present invention.

FIG. 10 is a cross-sectional view showing a cross-sectional structure of a logic chip along a line B1-B2 shown in FIG. 9.

FIG. 11 is a block diagram showing a configuration of a logic chip according to the first embodiment of the present invention.

FIG. 12 is a plan view showing a configuration of the inductor group included in a memory chip according to the first embodiment of the present invention.

FIG. 13 is a perspective view and a schematic view showing a configuration of an inductor included in a logic chip and an inductor included in a memory chip according to the first embodiment of the present invention.

FIG. 14 is a schematic view showing a positional relationship of inductor groups included in each of a plurality of memory chips according to the first embodiment of the present invention.

FIG. 15 is a schematic view showing a positional relationship of inductor groups included in a logic chip according to the first embodiment of the present invention.

FIG. 16 is a schematic view showing a relationship between an inductor group included in a logic chip and a memory chip (an inductor group included in a memory chip) during inductor communication according to the first embodiment of the present invention.

FIG. 17A is a schematic view showing a method for manufacturing a semiconductor module according to the first embodiment of the present invention.

FIG. 17B is a schematic view showing a method for manufacturing a semiconductor module according to the first embodiment of the present invention.

FIG. 17C is a schematic view showing a method for manufacturing a semiconductor module according to the first embodiment of the present invention.

FIG. 18A is a schematic view showing a method for manufacturing a semiconductor module according to the first embodiment of the present invention.

FIG. 18B is a schematic view showing a method for manufacturing a semiconductor module according to the first embodiment of the present invention.

FIG. 18C is a schematic view showing a method for manufacturing a semiconductor module according to the first embodiment of the present invention.

FIG. 19 is a schematic view showing a configuration of a semiconductor module according to a comparative example.

FIG. 20 is a graph showing power and delay time during data communication with respect to the number of stacked memory chips of a semiconductor module according to the first embodiment and a semiconductor module according to the comparative example of the present invention.

FIG. 21 is a schematic view showing a positional relationship of inductor groups included in a logic chip according to the second embodiment of the present invention.

FIG. 22 is a schematic view showing a relationship between an inductor group included in a logic chip and a memory chip (an inductor group included in a memory chip) during inductor communication according to the second embodiment of the present invention.

FIG. 23 is a schematic view showing a positional relationship of inductor groups included in each of a plurality of memory chips according to the second embodiment of the present invention.

FIG. 24A is a schematic view showing a method for manufacturing a semiconductor module according to the second embodiment of the present invention.

FIG. 24B is a schematic view showing a method for manufacturing a semiconductor module according to the second embodiment of the present invention.

FIG. 25 is a schematic view showing a positional relationship of inductor groups included in each of a plurality of memory chips according to the third embodiment of the present invention.

FIG. 26 is a schematic view showing a positional relationship of inductor groups included in a logic chip according to the third embodiment of the present invention.

FIG. 27 is a schematic view showing a relationship between an inductor group included in a logic chip and a memory chip (an inductor group included in a memory chip) during inductor communication according to the third embodiment of the present invention.

FIG. 28A is a schematic view showing a method for manufacturing a semiconductor module according to the third embodiment of the present invention.

FIG. 28B is a schematic view showing a method for manufacturing a semiconductor module according to the third embodiment of the present invention.

FIG. 28C is a schematic view showing a method for manufacturing a semiconductor module according to the third embodiment of the present invention.

FIG. 28D is a schematic view showing a method for manufacturing a semiconductor module according to the third embodiment of the present invention.

FIG. 29A is a schematic view showing a method for manufacturing a semiconductor module according to the third embodiment of the present invention.

FIG. 29B is a schematic view showing a method for manufacturing a semiconductor module according to the third embodiment of the present invention.

FIG. 30A is a schematic view showing a method for manufacturing a semiconductor module according to the fourth embodiment of the present invention.

FIG. 30B is a schematic view showing a method for manufacturing a semiconductor module according to the fourth embodiment of the present invention.

FIG. 30C is a schematic view showing a method for manufacturing a semiconductor module according to the fourth embodiment of the present invention.

FIG. 31A is a schematic view showing a method for manufacturing a semiconductor module according to the fourth embodiment of the present invention.

FIG. 31B is a schematic view showing a method for manufacturing a semiconductor module according to the fourth embodiment of the present invention.

FIG. 32A is a plan view showing a configuration of a seal ring and an inductor included in a memory chip according to the fifth embodiment of the present invention.

FIG. 32B is a cross-sectional view showing a cross-section of a seal ring and an inductor included in a memory chip along a line C1-C2 of FIG. 32A.

FIG. 33A is a plan view showing a configuration of a seal ring and an inductor included in a memory chip according to the fifth embodiment of the present invention.

FIG. 33B is a cross-sectional view showing a cross-section of a seal ring along a line J1-J2 of FIG. 33A.

FIG. 34A is a plan view showing a configuration of a seal ring and an inductor included in a memory chip according to the fifth embodiment of the present invention.

FIG. 34B is a cross-sectional view showing a cross-section of a seal ring along a line E1-E2 of FIG. 34A.

FIG. 35A is a plan view showing a method for manufacturing an inductor included in a memory cube according to the sixth embodiment of the present invention.

FIG. 35B is a side view showing a memory cube and an inductor included in a memory cube.

FIG. 36A is a plan view showing a method for manufacturing an inductor included in a memory cube according to the sixth embodiment of the present invention.

FIG. 36B is a cross-sectional view showing a cross-section of a memory cube along a line F1-F2 of FIG. 35A.

FIG. 37A is a plan view showing a method for manufacturing an inductor included in a memory cube according to the sixth embodiment of the present invention.

FIG. 37B is a side view showing a memory cube and an inductor included in a memory cube.

FIG. 38A is a plan view showing a method for manufacturing an inductor included in a memory cube according to the sixth embodiment of the present invention.

FIG. 38B is a cross-sectional view showing a cross-section of a memory cube along a line G1-G2 of FIG. 37A.

FIG. 39 is a perspective view showing a configuration of a power supply line of a semiconductor module according to the seventh embodiment of the present invention.

FIG. 40 is a cross-sectional view showing a cross-section of a semiconductor module along a line H1-H2 of FIG. 39.

FIG. 41A is a side view showing a method for manufacturing a power supply line of a semiconductor module according to the seventh embodiment of the present invention.

FIG. 41B is a side view showing a method for manufacturing a power supply line of a semiconductor module according to the seventh embodiment of the present invention.

FIG. 42 is a perspective view showing an integrated circuit on which a semiconductor module according to the eighth embodiment of the present invention is mounted.

FIG. 43 is a cross-sectional view showing an integrated circuit of FIG. 42.

FIG. 44A is a cross-sectional view showing a cross-section of an integrated circuit on which a semiconductor module according to the eighth embodiment of the present invention is mounted.

FIG. 44B is a cross-sectional view showing a cross-section of an integrated circuit on which a semiconductor module according to the eighth embodiment of the present invention is mounted.

FIG. 44C is a cross-sectional view showing a cross-section of an integrated circuit on which a semiconductor module according to the eighth embodiment of the present invention is mounted.

FIG. 45 is a flowchart showing a method for mounting a semiconductor module according to the ninth embodiment of the present invention.

### DESCRIPTION OF EMBODIMENTS

For example, in a conventional stacked memory cube, a memory chip is connected to a substrate or a logic chip using a TSV or micro bump. For example, when the memory chip and the logic chip are connected using the micro bump, a gap is formed between the memory chip and the logic chip by the length (size) of the micro bump. When the gap is formed between the memory chip and the logic chip, the thermal resistance increases accordingly, the thermal conductivity decreases, and it becomes difficult to remove heat.

In addition, in a conventional technique for contactless communication between two chips, respective inductors in the two chips are arranged on the same plane. That is, the angle formed between the surfaces on which the respective inductors in the two chips are arranged is 0 degrees, and since the inductors are arranged on the sides facing each other in the two chips, the number of inductors is determined by the length of the side of the chip. For example, in order to increase the memory capacity using the conventional technique for contactless communication between two chips, it is necessary to increase the chip size. However, as the chip size increases, the length of a wiring and wiring loads (capacitance) increase, and the power consumed by the chip increases. That is, it is difficult to increase the memory capacity and reduce the power consumption in the conventional technique for contactless communication between two chips.

Furthermore, in the conventional technique for contactless communication between two chips, the angle formed between the surfaces on which the respective coils in the two chips are arranged is an arbitrary angle, but in the two chips, since the coils are arranged on the sides facing each other, the number of the coils is determined by the length of the side of the chip. Therefore, when the memory capacity is increased using the conventional technique for contactless communication between two chips, the length of the wiring and wiring loads (capacity) increase, and the power consumed by the chip increases. That is, it is difficult to increase the memory capacity and reduce the power consumption in the conventional technique for contactless communication between two chips.

In view of such problems, an object of an embodiment of the present invention is to provide a semiconductor module using inductor communication that has good thermal conductivity and excellent heat removal characteristics and can increase the memory capacity and reduce the power consumption, and a method for manufacturing the same.

Hereinafter, embodiments of the present invention will be described with reference to the drawings and the like. However, the present invention can be implemented in many different aspects, and should not be construed as being limited to the description of the embodiments exemplified below. In order to make the description clearer, the drawings may be schematically represented with respect to the width, thickness, shape, and the like of each part as compared with the actual embodiment, but the drawings are merely examples, and do not limit the interpretation of the present invention. Furthermore, in the present specification and the drawings, elements similar to those described above with respect to the above-described figures are denoted by the same reference signs (or reference signs denoted by a, b, and the like after numerals) and the description may be omitted as appropriate. Furthermore, the terms “first” and “second” with respect to the respective elements are convenient signs used to distinguish the respective elements, and do not have any further meaning unless otherwise specified.

In an embodiment of the present invention, in the case where a member or region is “on (or under)” another member or region, this includes, unless otherwise limited, not only the case where it is directly above (or below) the other member or region, but also the case where it is above (or below) the other member or region, that is, the case where another component is included between above (or below) the other member or region.

In an embodiment of the present invention, a direction D1 intersects a direction D2, and a direction D3 intersects the direction D1 and the direction D2 (D1D2 plane). The direction D1 is referred to as the first direction, the direction D2 is referred to as the second direction, and the direction D3 is referred to as the third direction.

In an embodiment of the present invention, in the case where the terms “same” and “match” are used, the same and match may include tolerances within the scope of the design. Furthermore, in an embodiment of the present invention, in the case where tolerances within the scope of the design are included, the expression “substantially the same” and “substantially match” may be used.

### First Embodiment

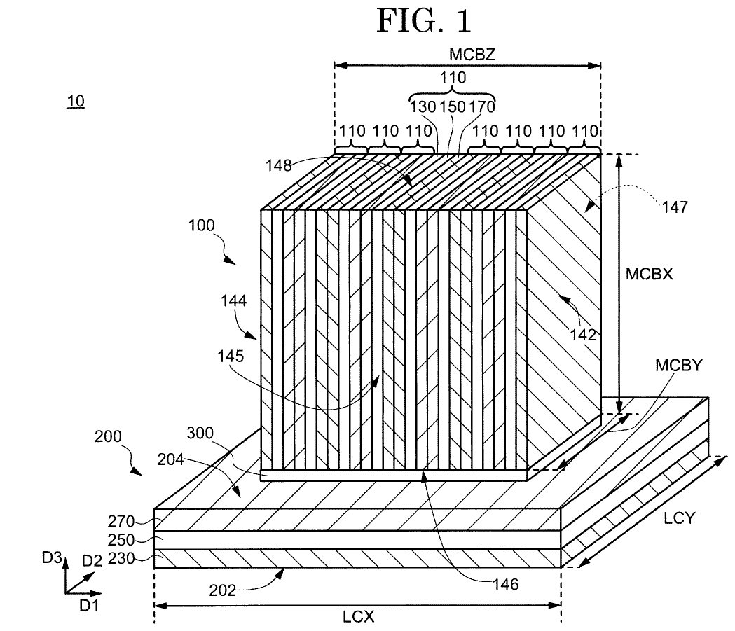

A semiconductor module 10 according to the first embodiment will be described with reference to FIG. 1 to FIG. 20.

### [1-1. Overview of Semiconductor Module 10]

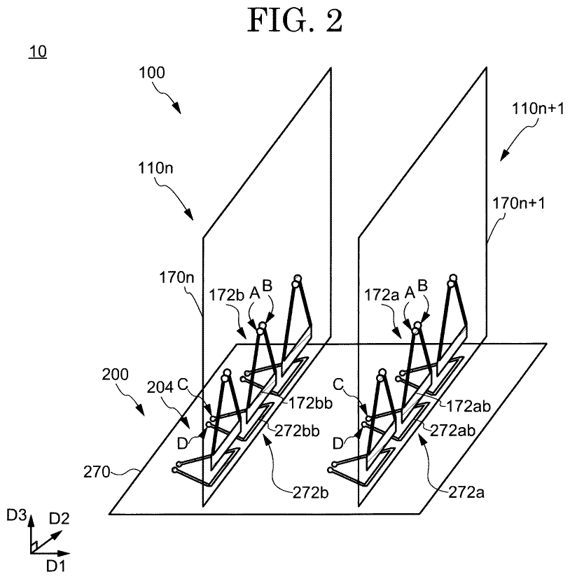

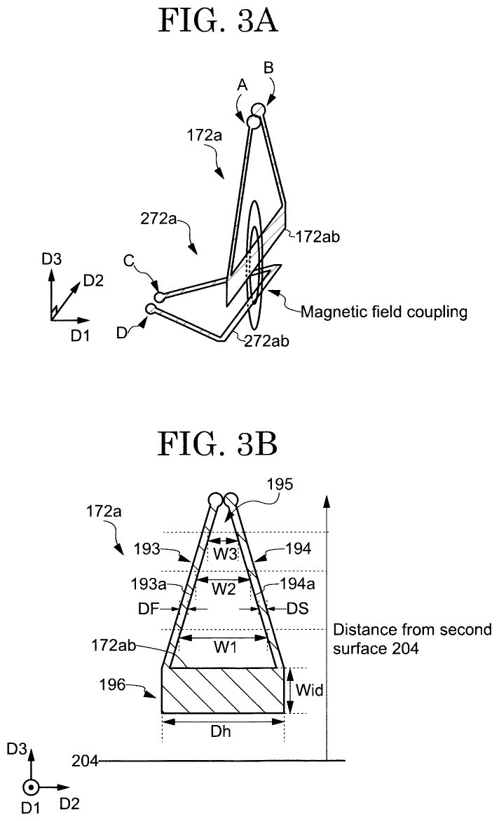

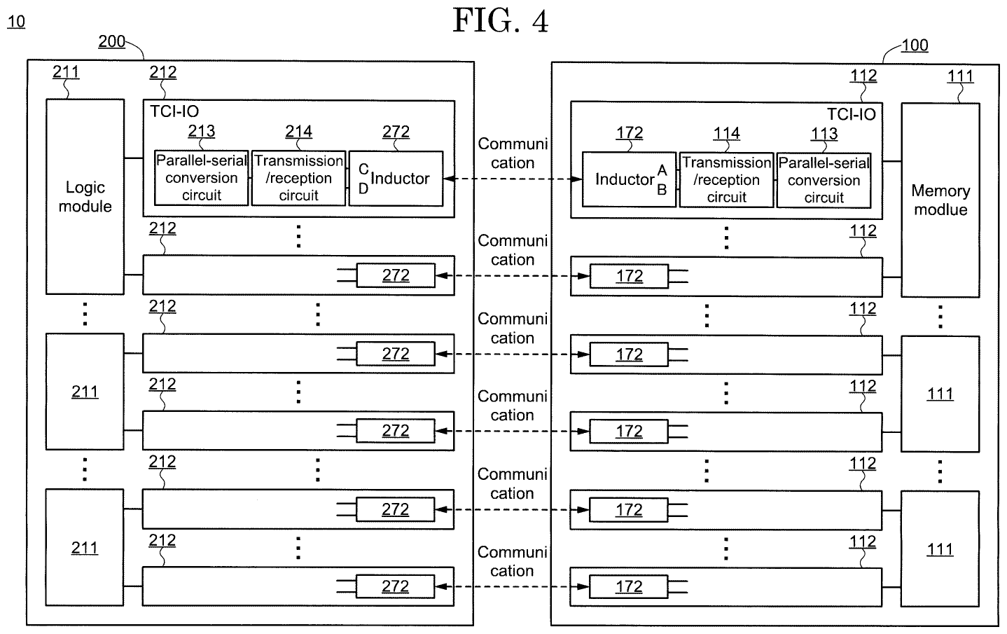

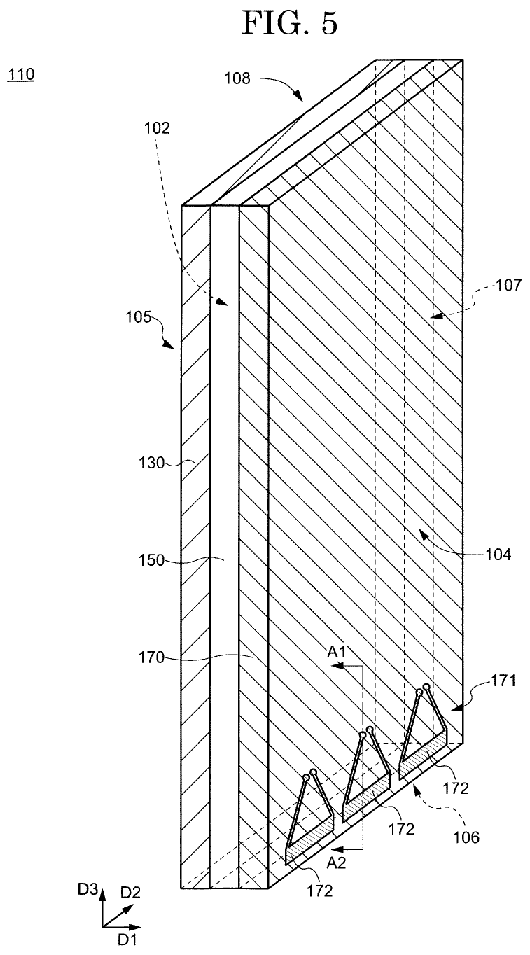

An overview of the semiconductor module 10 will be described with reference to FIG. 1 to FIG. 4. FIG. 1 is a perspective view showing a configuration of the semiconductor module 10. FIG. 2 is a perspective view showing a plurality of inductors 272 included in a logic chip 200 and an inductor group 171 included in a plurality of memory chips 110. FIG. 3A is a perspective view showing a configuration of the inductor 272 on the logic chip 200 and the inductor 172 on the memory chip 110 shown in FIG. 2, and FIG. 3B is a diagram showing the positional relationship between the logic chip 200 and the inductor 172 on the memory chip 110 shown in FIG. 2. FIG. 4 is a block diagram showing a configuration of the semiconductor module 10.

First, the configuration of the semiconductor module 10 will be described with reference to FIG. 1 to FIG. 3. As shown in FIG. 1, the semiconductor module 10 includes a memory cube 100, the logic chip 200, and an adhesive layer 300. The logic chip 200 may be referred to as a semiconductor chip.

The memory cube 100 includes a configuration in which the plurality of memory chips 110 is stacked and is arranged on a second surface 204 of the logic chip 200. Each of the plurality of memory chips 110 includes a similar configuration. For example, each of the plurality of memory chips 110 includes a transistor layer 130, a wiring layer 150, and an inductor layer 170. For example, the logic chip 200 includes a transistor layer 230, a wiring layer 250, and an inductor layer 270, and includes a first surface 202 parallel to the direction D1 (first direction) and the direction D2 (second direction) intersecting the first direction, and a second surface 204 opposite the first surface 202. The first surface 202 is a surface opposite the surface on which the wiring layer 250 is arranged with respect to the transistor layer 230, and the second surface 204 is a surface opposite the surface on which the wiring layer 250 is arranged with respect to the inductor layer 270. The adhesive layer 300 is arranged between a second side surface 146 of the memory cube 100 and the second side surface 204 of the logic chip 200, and connects the memory cube 100 and the logic chip 200.

As shown in FIG. 2, each inductor layer 170 of the plurality of memory chips 110 includes a plurality of inductors 172 (first inductor) arranged in the direction D3 (third direction) perpendicular to the first direction and the second direction (i.e., the first surface 202 and the second surface 204). The logic chip 200 includes the plurality of inductors 272 (second inductor) parallel to the position where the plurality of inductors 172 is arranged and arranged close to the second surface 204 in parallel. In addition, the inductor layer 270 includes the plurality of inductors 272.

For example, the plurality of memory chips 110 includes a memory chip 110n and a memory chip 110n+1 arranged adjacent to the memory chip 110n. The memory chip 110n includes an inductor layer 170n. The inductor layer 170n includes the plurality of inductors 172, and the plurality of inductors 172 include an inductor 172b including one straight side 172bb.

Similar to the memory chip 110n, the memory chip 110n+1 includes an inductor layer 170n+1. The inductor layer 170n+1 includes the plurality of inductors 172, and the plurality of inductors 172 include an inductor 172a including one straight side 172ab. Similar to the inductor 172b and the inductor 172a, one straight side 172bb and one straight side 172ab are close to and parallel to the second surface 204.

The plurality of inductors 172 is arranged in parallel in the second direction. The inductor 172 includes a terminal A and a terminal B. Although details will be described later, the inductor 172 is electrically connected to a transmission/reception circuit 114 using the terminal A and the terminal B.

The plurality of inductors 272 is arranged in a matrix in the first direction and the second direction. The plurality of inductors 272 includes an inductor 272a including one straight side 272ab and an inductor 272b including one straight side 272bb. The inductor 272 includes a terminal C and a terminal D. Although details will be described later, the inductor 272 is electrically connected to a transmission/reception circuit 214 using the terminal C and the terminal D.

As shown in FIG. 2 and FIG. 3A, for example, the shape of the inductor 172 and the shape of the inductor 272 are triangular. Since the memory chip 110 is standing perpendicular to the logic chip 200, the inductor 172 faces the inductor 272 at 90 degrees. Among the plurality of inductors 172 and the plurality of inductors 272, one inductor 172 and one inductor 272 opposed to each other are magnetically coupled to each other, so that the inductors can communicate with each other one-to-one. For example, the communication between the inductors associated with the magnetic field coupling is referred to as inductor communication, signal communication, data communication, or the like. In addition, the shape of the inductor 172 and the shape of the inductor 272 are not limited to triangular. For example, the shape of the inductor 172 and the shape of the inductor 272 may be trapezoidal or pentagonal. The shape of the inductor 172 and the shape of the inductor 272 may be any shape capable of inductor communication.

As shown in FIG. 2 or FIG. 3A, for example, the inductor 172a and the inductor 272a are opposed to each other at 90 degrees, and can communicate one-to-one by magnetic field coupling. More specifically, effective inductor communication is performed by the base of the triangle of the inductor 172a (one straight side 172ab) and the base of the triangle of the inductor 272a overlapping one straight side 172ab (one straight side 272ab). One straight side 172ab mainly has a function for performing inductor communication with one straight side 272ab. In the inductor 172a, the two sides except one straight side 172ab mainly have a function for supplying a current to one straight side 172ab. Similar to the inductor 172a, in the inductor 272a, two sides except one straight side 272ab mainly have a function for supplying a current to one straight side 272ab. The inductor 172b and the inductor 272b have the same configuration and function as the inductor 172a and the inductor 272a.

As shown in FIG. 3B, in a front view, each of the plurality of inductors 172 includes a first portion 193 including a first side 193a, extending in the direction D3, and having a finite first width DF in the direction D2, a second portion 194 including a second side 194a, extending in the direction D3, and having a finite second width DS in the direction D2, and a third portion 196 including one straight side close to the second surface 204 and parallel to the second surface 204 (e.g., one straight side 172ab), including a length D2 extending in the direction D2 and parallel to the direction D2, and having a finite third width Wid in the third direction. Furthermore, in the inductor 172a, the distance between the first side 193a and the second side 194a cut parallel to the second surface 204 (a distance W1, a distance W2, and a distance W3) becomes shorter with increasing distance away from the second surface 204 in parallel in the direction D3. That is, the distance W1, the distance W2, and the distance W3 are shortened in this order. In addition, the inductor 172a is arranged perpendicular to the second side surface 146 of the memory cube 100. Furthermore, in a front view, the shape of a region 195 formed by a line extending the first side 193a and the second side 194a in the direction D3 and a side extending one straight side (for example, 172ab) in the direction D2 is triangular. In addition, the shape of the region 195 is not limited to triangular. For example, the inductor 172a may be trapezoidal including a fourth portion (not shown) including a third side (not shown) between the first side 193a and one straight side, and a fifth portion (not shown) including a fourth side (not shown) between the second side 194a and one straight side, and may be pentagonal, and the shape of the region 195 may be trapezoidal or pentagonal. The shape of the inductor 172a and the shape of the region 195 may be any shape capable of inductor communication. The inductor 272a may have the same configuration and function as the inductor 172a. Furthermore, in the present specification and the drawings, viewing a plane parallel to the direction D2 and the direction D3 from the direction D1 is referred to as a front view.

Next, an overview of an electrical circuit configuration of the semiconductor module 10 will be described with reference to FIG. 4. As shown in FIG. 4, the memory cube 100 includes a plurality of magnetic field coupled chip-to-chip interfaces (Through Chip Interface-IO (TCI-IO)) 112 and a plurality of memory modules 111. The plurality of TCI-IOs 112 is electrically connected to the memory module 111.

The TCI-IO 112 includes the inductor 172, the transmission/reception circuit 114, and a parallel-serial conversion circuit 113. The inductor 172 is electrically connected to the transmission/reception circuit 114 using the terminal A and the terminal B.

The transmission/reception circuit 114 is electrically connected to the parallel-serial conversion circuit 113. The parallel-serial conversion circuit 113 is electrically connected to the memory module 111.

The inductor 172 has a function for performing contactless inductor communication with the inductor 272 of the logic chip 200.

For example, the transmission/reception circuit 114 has a function for amplifying a signal (data) received by the inductor 172 and a function for removing noise from the received signal (data). In addition, for example, the transmission/reception circuit 114 has a function for transmitting a desired signal (data) converted by using the parallel-serial conversion circuit 113 onto a radio wave. The signal received by the inductor 172 includes a number of parallel signals from the logic chip 200. The desired signal includes many parallel signals from the memory module 111.

For example, in step 1, the parallel-serial conversion circuit 113 performs parallel-serial conversion of the many parallel signals from the logic chip 200 and converts the parallel-serial signals into a serial signal. The serial signal is transferred at high-speed using a single signal path (wiring). In step 2, the parallel-serial conversion circuit 113 performs serial-to-parallel conversion on the serial signal immediately before the memory module 111 to return the serial signal to the plurality of parallel signals, and then transmits the many parallel signals to the memory module 111. For example, in the case where a signal (data) is transmitted from the memory module 111 to the logic chip 200, the parallel-serial conversion circuit 113 performs step 1 following step 2. For example, the parallel-serial conversion circuit 113 is referred to as a SerDes circuit (Serialize and Deseriarise Circuit).

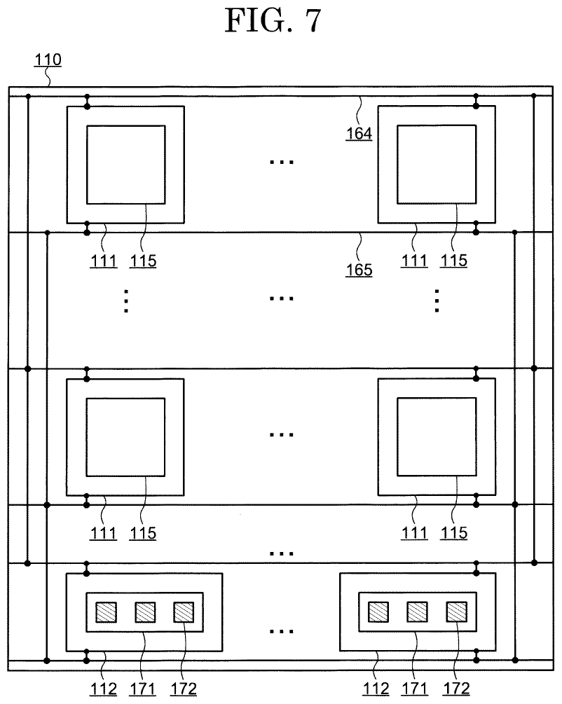

For example, the memory module 111 includes a function for generating the many parallel signals to be transmitted, and a function for controlling the many received parallel signals and storing them in a memory cell array 115 (see FIG. 7).

The logic chip 200 includes a plurality of magnetic field coupled chip-to-chip interfaces (Through Chip Interface-IO (TCI-IO)) 212 and a plurality of logic modules 211. The plurality of TCI-IOs 212 is electrically connected to the logic module 211.

The TCI-IO 212 includes the inductor 272, the transmission/reception circuit 214, and a parallel-serial conversion circuit 213. The inductor 272 is electrically connected to the transmission/reception circuit 214 using the terminal C and the terminal D. The transmission/reception circuit 214 is electrically connected to the parallel-serial conversion circuit 213. The parallel-serial conversion circuit 213 is electrically connected to the logic module 211.

The configurations and functions of the inductor 272, the transmission/reception circuit 214, the parallel-serial conversion circuit 213, and the logic module 211 are similar to the configurations and functions of the inductor 172, the transmission/reception circuit 114, the parallel-serial conversion circuit 113, and the memory module 111. Therefore, the descriptions of the configurations and functions of the inductor 272, the transmission/reception circuit 214, the parallel-serial conversion circuit 213, and the logic module 211 will be omitted here.

The semiconductor module 10 according to the first embodiment includes the above-described functions and configurations. Signals are transmitted and received between the inductor 172 included in the memory chip 110 and the inductor 272 included in the logic chip 200 using contactless inductor communication. The distance between the memory chip 110 (inductor 172) and the logic chip 200 (inductor 272) in the semiconductor module 10 is substantially the thickness of the adhesive layer 300. The distance between the memory chip 110 (inductor 172) and the logic chip 200 (inductor 272) in the semiconductor module 10 may be shorter than the distance between the memory chip 110 and the logic chip 200 connected using wirings, through electrodes, bumps, and the like. As a result, in the semiconductor module 10, the memory chip 110 and the logic chip 200 can be bonded to each other using the thin adhesive layer 300, so that the thermal resistance is low, and the heat removal characteristics are excellent. In addition, since the wiring resistance and the parasitic capacitance of the semiconductor module 10 are suppressed, communication using the semiconductor module 10 can suppress power consumption.

In addition, the semiconductor module 10 includes the memory cube 100 in which the plurality of memory chips 110 including the plurality of inductors 172 is stacked, and a large-capacity memory can be realized without increasing the size of the memory chip. That is, the semiconductor module 10 includes a large-capacity memory in which the wiring resistance and the parasitic capacitance of the semiconductor module 10 are suppressed as compared with a module having a large chip size. Therefore, memory with low power consumption and large capacity can be realized using the semiconductor module 10.

Furthermore, the semiconductor module 10 includes a configuration capable of performing one-to-one inductor communication between the inductor 172 and the inductor 272, which are arranged to face each other at 90 degrees. In addition, the plurality of inductors 172 is arranged parallel to the second side surface 146 of the memory cube 100, the plurality of inductors 272 is arranged parallel to the second surface 204 of the logic chip 200, and the inductors can communicate with each other one-to-one. As a result, it is easy to communicate large volumes of signals (data) in parallel.

Furthermore, for example, in the case where the shape of the inductor is rectangular or square, the distance between two adjacent inductors is constant regardless of the distance from the second surface 204. In the case where the distance between two adjacent inductors is constant, crosstalk occurs because the two adjacent inductors interfere with each other. On the other hand, as described above, for example, the semiconductor module 10 includes the plurality of triangular inductors 172, and the distance between the two sides of the inductor 172 decreases as the distance between the two sides increases from the second surface 204. That is, the distance between two adjacent inductors 172 increases as the distance from the second surface 204 increases. Therefore, since the two adjacent inductors 172 hardly interfere with each other, the semiconductor module 10 can suppress crosstalk.

### [1-2. Overview of Memory Cube 100]

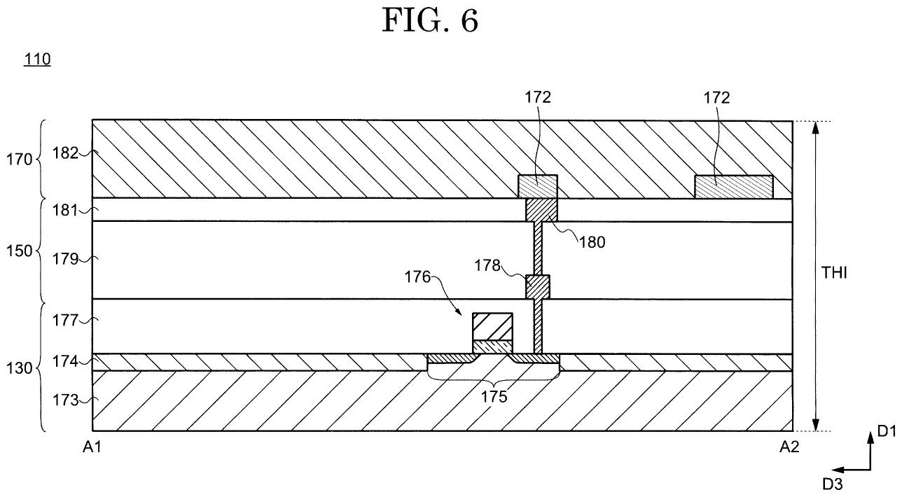

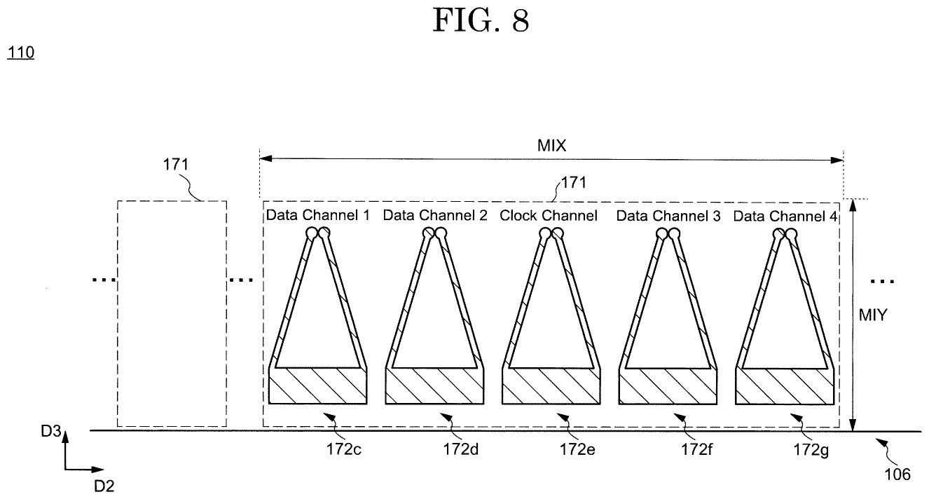

Next, an overview of the memory cube 100 will be described with reference to FIG. 1 and FIG. 5 to FIG. 8. FIG. 5 is a perspective view showing a configuration of the memory chip 110. FIG. 6 is a cross-sectional view showing a cross-sectional structure of the memory chip 110 along a line A1-A2 shown in FIG. 5. FIG. 7 is a block diagram showing a configuration of the memory chip 110. FIG. 8 is a plan view showing a configuration of the inductor group 171. The description of the same or similar configurations as those in FIG. 1 to FIG. 4 will be omitted here.

Referring to FIG. 1, as described in “1-1. Overview of Semiconductor Module 10”, the memory cube 100 includes a configuration in which the plurality of memory chips 110 is stacked in the direction D1. The memory cube 100 includes a first surface 142 parallel to the direction D2 and the direction D3 and a second surface 144 opposite the first surface 142 with respect to the direction D1 and parallel to the first surface 142. In addition, the memory cube 100 includes a first side surface 145 that is perpendicular to the first side 142 and the second side 144, the second side surface 146 that is adjacent to the first side surface 145, a third side surface 147 that is adjacent to the second side surface 146, and a fourth side surface 148 that is adjacent to the third side surface 147 and the first side surface 145. In addition, the second side surface 146 is in contact with the adhesive layer 300, and the memory cube 100 is arranged on the second surface 204 of the logic chip 200.

As shown in FIG. 1 and FIG. 5, for example, each of the plurality of memory chips 110 includes the transistor layer 130, the wiring layer 150, and the inductor layer 170.

For example, each of the plurality of memory chips 110 includes the memory chip 110n, the memory chip 110n+1 adjacent to the memory chip 110n, a memory chip 110n+2 adjacent to the memory chip 110n+1, a memory chip 110n+3 adjacent to the memory chip 110n+2, and a memory chip 110n+4 adjacent to the memory chip 110n+3.

In the case where each of the plurality of memory chips 110 is not distinguished, the memory chip is represented as the memory chip 110. In the case where each of the plurality of memory chips 110 is distinguished, the memory chip is represented as the memory chip 110n, the memory chip 110n+1, the memory chip 110n+2, and the like.

Similar to the plurality of memory chips 110, in the case where a plurality of inductor groups 171 and the plurality of inductors 172 are not distinguished, the inductor group is represented as the inductor group 171 and the inductor is represented as the inductor 172. In the case where the plurality of inductor groups 171 and the plurality of inductors 172 are distinguished, the inductor group is represented as inductor groups 171a, 171b, or the like, and the inductor is represented as the inductors 172a, 172b, or the like.

As shown in FIG. 5, the memory chip 110 includes a first surface 102 parallel to the direction D2 and the direction D3, and a second surface 104 opposite the first surface 102 with respect to direction D1. The first surface 102 is a surface opposite the surface on which the wiring layer 150 is arranged with respect to the transistor layer 130, and the second surface 104 is a surface opposite the surface on which the wiring layer 150 is arranged with respect to the inductor layer 170. The first surface 102 and the second surface 104 are parallel to the first surface 142 and the second surface 144.

In addition, the memory chip 110 includes a first side surface 105 perpendicular to the first side surface 102 and the second side surface 104, a second side surface 106 adjacent to the first side surface 105, a third side surface 107 adjacent to the second side surface 106, and a fourth side surface 108 adjacent to the third side surface 107 and the first side surface 105. The first side surface 105 is part of the first side surface 145, the second side surface 106 is part of the second side surface 146, the third side surface 107 is part of the third side surface 147, and the fourth side surface 108 is part of the fourth side surface 148.

The inductor layer 170 includes the plurality of inductor groups 171. Each of the plurality of inductor groups 171 includes the plurality of inductors 172. For example, the inductor group 171 includes five inductors 172. The plurality of inductor groups 171 includes the plurality of inductors 172 arranged perpendicular to the direction D2 and the direction D3 (i.e., the first surface 102 and the second surface 104) and parallel in the direction D3. Each of the plurality of inductor groups 171 is arranged away from the fourth side surface 108, close to the second side surface 146, and extends in the direction D2. In addition, the number of the plurality of inductors 172 included in the inductor group 171 is not limited to five. The number of the inductors 172 can be appropriately changed depending on the specifications, applications, and the like of the semiconductor module 10.

As shown in FIG. 6, for example, the transistor layer 130 includes portions of a substrate 173, an element isolation region 174, an activation region 175, a transistor 176, an insulating layer 177, and a wiring 178. For example, the substrate 173 is a Si substrate or a Si-wafer.

The wiring layer 150 includes a multi-layer wiring structure in which the wiring and the insulating layer are alternately stacked. For example, the wiring layer 150 includes portions of the wiring 178, an insulating layer 179, a wiring 180, and an insulating layer 181. The number of layers of the multi-layer wiring in the wiring layer 150 is not limited to the two layers shown in FIG. 6. The number of layers of the multi-layer wiring in the wiring layer 150 may be three or more. The number of layers of the multi-layer wiring in the wiring layer 150 can be appropriately changed depending on the specifications, applications, and the like of the semiconductor module 10.

For example, the inductor layer 170 includes an insulating layer 182 and the plurality of inductors 172. In addition, the inductor layer 170 includes the plurality of inductor groups 171.

As shown in FIG. 7, the memory chip 110 includes the plurality of memory modules 111, the plurality of TCI-IOs 112, a power supply wiring 164, and a ground wiring 165. Each of the plurality of memory modules 111 includes the memory cell array 115. Each of the plurality of TCI-IOs 112 includes the plurality of inductor groups 171, and the inductor group 171 includes the plurality of inductors 172.

The memory module 111 has a function for controlling the storage of the signal (data) to the memory cell array 115, the reading of the signal (data) from the memory cell array 115, the transmitting of the signal (data) to the TCI-IO 112, and the receiving of the signal (data) from the TCI-IO 112, and the like.

The memory cell array 115 includes a plurality of memory cells (not shown). For example, each of the plurality of memory cell arrays 115 is a SRAM (Static Random Access Memory), and each of the plurality of memory cells is a SRAM cell. The SRAM, the SRAM cell, and the memory module 111 for the SRAM may employ a technique used in the technical field of SRAM. Therefore, the description will be omitted here. In addition, the plurality of memory cell arrays 115 and the plurality of memory cells may be memory cell arrays and memory cells other than the SRAM, and may be, for example, a DRAM (Dynamic Random Access Memory) and a DRAM cell, and a MRAM (Magnetoresistive Random Access Memory) and a MRAM cell.

The plurality of memory modules 111 and the plurality of TCI-IOs 112 are electrically connected to the power supply wiring 164 and the ground wiring 165. For example, the power supply wiring 164 and the ground wiring 165 are electrically connected to an external circuit (not shown), and are supplied with power (VDD), VSS, and the like. For example, VDD is 1 V, 3 V, or the like. For example, VSS is a ground voltage, 0 V, or the like.

As shown in FIG. 8, the plurality of inductor groups 171 is close to the second side surface 106 of the memory chip 110 and is aligned parallel in the direction D2. Each of the plurality of inductor groups 171 includes the plurality of inductors 172. For example, the inductor group 171 includes five inductors 172c, 172d, 172e, 172f, and 172g. For example, the plurality of inductors 172 includes an inductor having a function for data communication (data transmission) and an inductor having a function for clock communication (clock transmission). The inductor group 171 may be referred to as a channel. For example, the inductor 172c has a function for one-to-one data communication with the corresponding inductor 272 and is referred to as a first data channel (Data Channel 1). The inductors 172d, 172f, and 172g have similar functions and configurations as the inductor 172c and are referred to as a second data channel (Data Channel 2), a third data channel (Data Channel 3), and a fourth data channel (Data Channel 4), respectively. For example, the inductor 172e has a function for one-to-one clock communication (clock transmission) with the corresponding inductor 272 and is referred to as a clock channel (Clock Channel). Each inductor 172 may perform one-to-one inductor communication with a corresponding inductor 272 in response to a clock received by the clock communication (synchronously), and each inductor 172 may perform one-to-one inductor communication with the corresponding inductor 272 without synchronizing (asynchronously) with the clock received by the clock communication. In addition, for example, the inductor 172e does not have the function for clock communication, and has a similar function and configuration as the inductor 172c, and the inductor 172 may perform one-to-one inductor communication with the corresponding inductor 272 asynchronously. The inductor communication of the semiconductor module 10 can be appropriately selected based on the specifications, applications, and the like of the semiconductor module 10 without departing from the scope of the present invention.

For example, a length MCBZ of the memory cube 100 in the direction D1 (see FIG. 1) is 5.12 mm, a length MCBY of the memory cube 100 in the direction D2 (see FIG. 1) is 5.00 mm, and a length MCBX of the memory cube 100 in the direction D3 (see FIG. 1) is 5.00 mm. For example, a thickness THI (see FIG. 6) of the memory chip 110 is 80 μm. For example, a length MIX of the inductor group 171 parallel to the direction D2 (see FIG. 8) is 600 μm, and a length MIY of the inductor group 171 parallel to the direction D3 (see FIG. 8) is 160 μm. For example, suppose that the memory chip 110 is manufactured using a CMOS process of 2 nm, the memory cube 100 is configured with the above-described size in which 64 memory chips 110 are stacked, the inductor group 171 is configured with the above-described size including four data channels, and the data transfer rate is 200 Gbps. In addition, for example, the data rate of one data channel of the inductor 172 and the inductor 272 is 50 Gbps, the frequency of the system clock of the clock channel is 0.5 GHZ, and the clock frequencies of the transmission/reception circuits 114 and 214 are 250 GHz.

The memory capacity the memory chip 110 is 0.25 GB, and the memory capacity of the memory cube 100 is 16 GB. In addition, one inductor group 171 includes four data channels, that is, four data channels per memory chip 110, and the data transfer rate is 800 Gbps=100 GBps per memory chip 110. Therefore, the total data transfer rate of the memory cube 100 is 100 GBps×64=6.4 TBps.

### [1-3. Overview of Logic Chip 200]

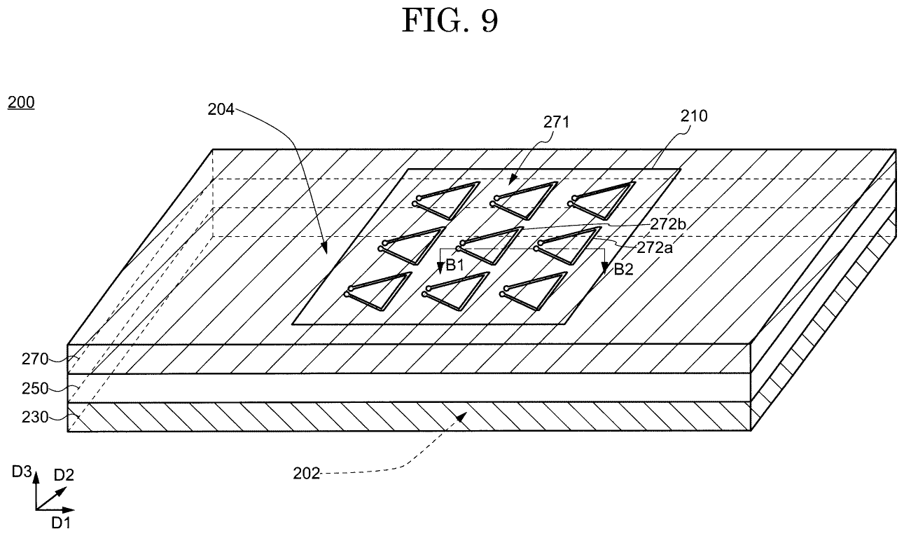

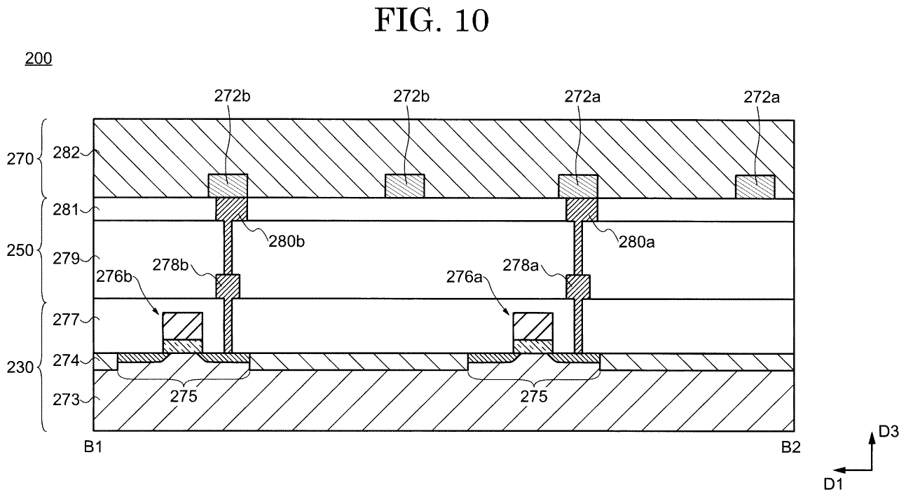

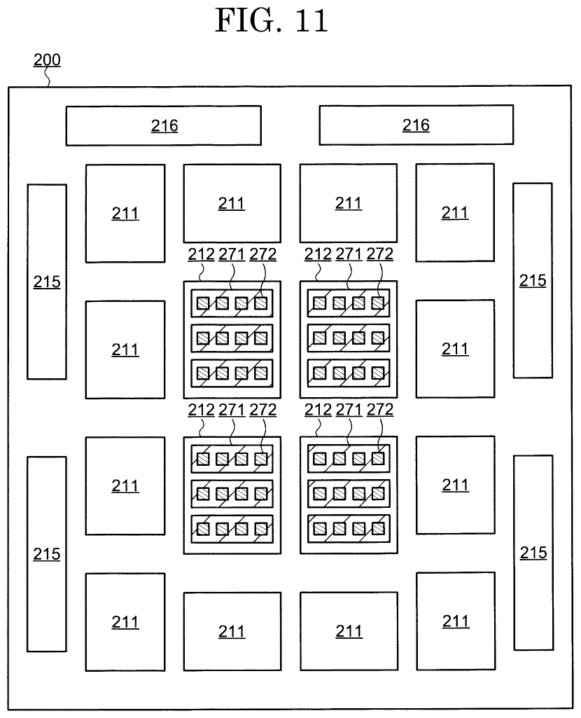

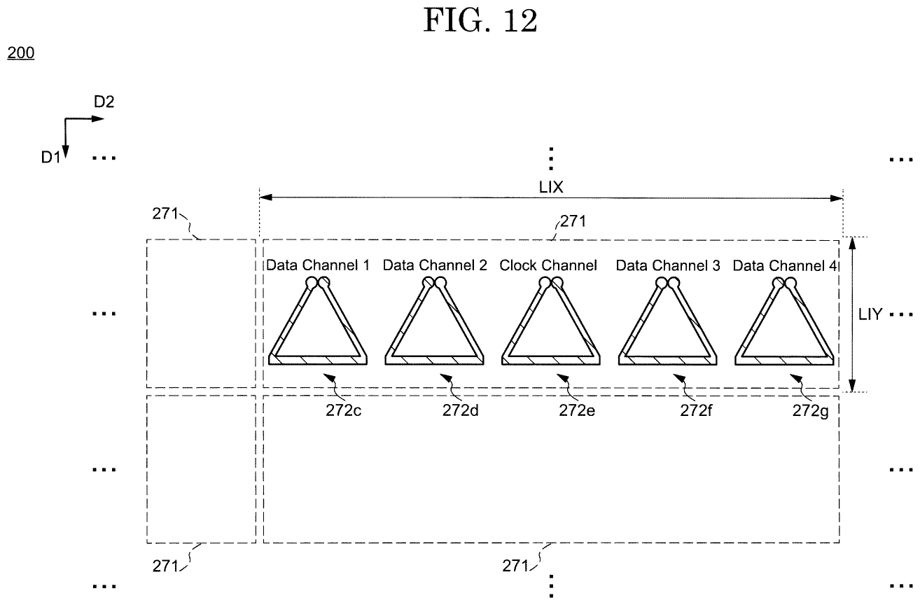

Next, an overview of the logic chip 200 will be described with reference to FIG. 1 and FIG. 9 to FIG. 12. FIG. 9 is a perspective view showing a configuration of the logic chip 200. FIG. 10 is a cross-sectional view showing a cross-sectional structure of the logic chip 200 along a line B1-B2 shown in FIG. 9. FIG. 11 is a block diagram showing a configuration of the logic chip 200. FIG. 12 is a plan view showing a configuration of an inductor group 271. The description of the same or similar configurations as those in FIG. 1 to FIG. 8 will be omitted here.

Referring to FIG. 1, as described in “1-1. Overview of Semiconductor Module 10”, the logic chip 200 includes a configuration in which the transistor layer 230, the wiring layer 250, and the inductor layer 270 are stacked in this order in the direction D3, and includes the first surface 202 parallel in the direction D1 and the direction D2, and the second surface 204 opposite the first surface 202. The first surface 202 is a surface opposite the surface on which the wiring layer 250 is arranged with respect to the transistor layer 230, and the second surface 204 is a surface opposite the surface on which the wiring layer 250 is arranged with respect to the inductor layer 270.

As shown in FIG. 1 and FIG. 9, for example, the logic chip 200 includes the transistor layer 230, the wiring layer 250, and the inductor layer 270.

The inductor layer 270 includes a plurality of inductor groups 271. Each of the plurality of inductor groups 271 includes the plurality of inductors 272. For example, the inductor group 271 includes five inductors 272. The plurality of inductor groups 271 is arranged in a matrix parallel to the direction D1 and the direction D2 (i.e., the first surface 202 and the second surface 204). In addition, the plurality of inductors 272 is arranged in a matrix parallel to the direction D1 and the direction D2 (i.e., the first surface 202 and the second surface 204). Furthermore, the number of the plurality of inductors 272 included in the inductor group 271 is not limited to five. The number of the inductors 272 can be appropriately changed depending on the specifications, applications, and the like of the semiconductor module 10.

In addition, the logic chip 200 includes a memory cube placement region 210 in a substantially central portion. The memory cube placement region 210 is in contact with the adhesive layer 300 and the adhesive layer 300 is arranged. The memory cube 100 is arranged on the memory cube placement region 210. In addition, the memory cube placement region 210 overlaps the plurality of inductor groups 271. For example, the plurality of inductor groups 271 is arranged inside the memory cube placement region 210 in the front view.

In the case where the plurality of inductor groups 271 and the plurality of inductors 272 are not distinguished, the inductor group is represented as the inductor group 271, and the inductor is represented as the inductor 272. In the case where the plurality of inductor groups 271 and the plurality of inductors 272 are distinguished, the inductor group is represented as the inductor groups 271a, 271b, or the like, and the inductor is represented as the inductors 272a, 272b, or the like.

As shown in FIG. 10, for example, the transistor layer 230 includes a substrate 273 including an element isolation region 274 and an activation region 275, a transistor 276a, a transistor 276b, an insulating layer 277, a portion of a wiring 278a, and a portion of a wiring 278b. For example, the substrate 273 is a Si substrate or a Si-wafer.

The wiring layer 250 includes the multi-layer wiring structure in which the wiring and the insulating layer are alternately stacked. For example, the wiring layer 250 includes a portion of the wiring 278a, a portion of the wiring 278b, an insulating layer 279, a wiring 280a, a wiring 280b, and an insulating layer 281. The number of layers of the multi-layer wiring in the wiring layer 250 is not limited to the two layers shown in FIG. 10. The number of layers of the multi-layer wiring in the wiring layer 250 may be three or more. The number of layers of the multi-layer wiring in the wiring layer 250 can be appropriately changed depending on the specifications, applications, and the like of the semiconductor module 10.

For example, the inductor layer 270 includes an insulating layer 282 and the plurality of inductors 272 (inductor 272a, inductor 272b). The inductor layer 270 includes the plurality of inductor groups 271.

As shown in FIG. 11, for example, the logic chip 200 includes the plurality of logic modules 211, the plurality of TCI-IOs 212, a plurality of DRAM interfaces (Dynamic Random Access Memory (DRAM) IO) 215, and a plurality of external IOs 216. Each of the plurality of TCI-IOs 212 includes the plurality of inductors 271, and the inductor group 271 includes the plurality of inductors 272. In addition, the configuration of the logic chip 200 shown in FIG. 11 is an example, and the configuration of the logic chip 200 is not limited to the example shown in FIG. 11. For example, the logic chip 200 may not include the DRAMIO 215.

The logic module 211 has a function for controlling the transmission of the signal (data) to the TCI-IO 212, and the reception of the signal (data) from the TCI-IO 212, and the like. In addition, the logic module 211 has a function for driving the memory module 111 in the memory chip 110. For example, the logic module 211 transmits a signal for driving the memory module 111 via the TCI-IO 212. For example, the logic module 211 may include a calculation circuit such as a CPU (Central Processing Unit).

For example, the DRAMIO 215 is electrically connected to a DRAM module 400 (see FIG. 42) and has a function for transmitting and receiving signals between the DRAM module 400 and the logic chip 200. For example, the external IO 216 is electrically connected to the logic chip 200 and an external circuit (not shown, for example, a power supply circuit) and has a function for transmitting and receiving signals between the external circuit and the logic chip 200.

Each of the plurality of logic modules 211 is electrically connected to a portion of the plurality of TCI-IOs 212, a portion of the plurality of DRAMIOs 215, and a portion of the plurality of external IOs. For example, each of the plurality of logic modules 211 is supplied with power (VDD) and VSS from the external circuit, receives a control program stored in the DRAM module 400 from the DRAM module 400, and executes a process of the control program.

As shown in FIG. 12, the plurality of inductor groups 271 is arranged in a matrix in the direction D1 and the direction D2. Each of the plurality of inductor groups 271 includes the plurality of inductors 272. For example, the inductor group 271 includes five inductors 272c, 272d, 272e, 272f, and 272g. Similar to the plurality of inductors 172, for example, the plurality of inductors 272 includes an inductor having a function for data communication (data transmission) and an inductor having a function for clock communication (clock transmission). In addition, similar to the inductor group 171, the inductor group 271 may be referred to as a channel, and for example, the inductor 272c has a function for one-to-one data communication with the corresponding inductor 172 and is referred to as the first data channel (Data Channel 1). The inductors 272d, 272f, and 272g have the same functions and configurations as the inductor 272c and are referred to as the second data channel (Data Channel 2), the third data channel (Data Channel 3), and the fourth data channel (Data Channel 4), respectively. In addition, for example, the inductor 272e has a function for one-to-one clock communication (clock transmission) with the corresponding inductor 172 and is referred to as a clock channel (Clock Channel). Similar to each inductor 172, each inductor 272 may perform one-to-one inductor communication with the corresponding inductor 172 in response to the clock received by the clock communication (synchronously), and may perform one-to-one inductor communication with the corresponding inductor 172 without synchronizing (asynchronously) with the clock received by the clock communication. In addition, for example, the inductor 272e does not have the function for clock communication, and has a similar function and configuration as the inductor 272c, and the inductor 272 may perform one-to-one inductor communication with the corresponding inductor 172 asynchronously.

For example, a length LCX of the logic chip 200 in the direction D1 (see FIG. 1) is 12.00 mm, and a length LCY of the logic chip 200 in the direction D2 (see FIG. 1) is 12.00 mm. For example, similar to the thickness THI of the memory chip 110 (see FIG. 6), the thickness of the logic chip 200 in the direction D3 is 80 μm. For example, a length LIX of the inductor group 271 parallel in the direction D2 (see FIG. 12) is 600 μm, and a length LIY of the inductor group 271 parallel in the direction D1 (see FIG. 12) is 160 μm. For example, similar to the memory chip 110, the logic chip 200 is manufactured using the CMOS process of 2 nm, and the inductor group 271 is configured with the above-described size including four data channels. In addition, the data transfer rate, the data rate of one data channel, the frequency of the system clock, and the clock frequencies of the transmission/reception circuits 114 and 214 are as described in “1-2. Overview of the Memory Cube 100”.

### [1-4. Overview of Inductor 172 and Inductor 272]

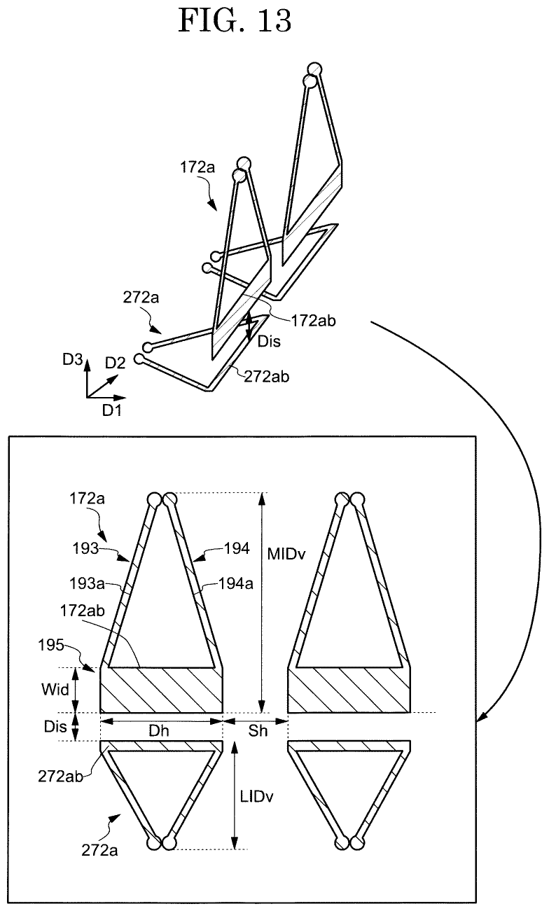

Next, an overview of the inductor 172 and the inductor 272 will be mainly described with reference to FIG. 13. FIG. 13 is a perspective view and a schematic view showing a configuration of the inductor 272 included in the logic chip 200 and the inductor 172 included in the memory chip 110. The description of the same or similar configurations as those in FIG. 1 to FIG. 12 will be omitted here.

The perspective view of the inductor 172a and the inductor 272a shown in FIG. 13 is an enlarged view of FIG. 2 with some parts omitted. As described in “1-1. Overview of Semiconductor Module 10”, the plurality of inductors 172 includes the inductor 172a including one straight side 172ab, and the plurality of inductors 272 includes the inductor 272a including one straight side 272ab. In addition, the inductor 172a and the inductor 272a are arranged to face each other at 90 degrees, and one straight side 172ab and one straight side 272ab are close to and parallel to the second surface 204.

In order to make the configuration of the inductor 172a and the inductor 272a easy to see, the plan view of the inductor 172a and the inductor 272a shown in FIG. 13 is shown to be parallel to the surface (second surface 204) formed in the direction D1 and the direction D2. In practice, since the memory chip 110 is arranged in the direction D3 (i.e., vertically arranged) with respect to the second surface 204 of the logic chip 200, the inductor 172a and the inductor 272a are arranged in the direction D3 with respect to the second surface 204 of the logic chip 200.

As shown in FIG. 13, the distance between the inductor 172a and the inductor 272a and the distance between one straight side 172ab and one straight side 272ab are indicated by a distance Dis. The height of the inductor 172a is indicated by a height MIDv, the width of one straight side 172ab in the direction D3 is indicated by a width Wid, the length of one straight side 172ab and one straight side 272ab in the direction D2 is indicated by a length Dh, and the height of the inductor 272a is indicated by a height LIDv. In addition, the interval (distance) between the adjacent inductors 172 and the interval (distance) between the adjacent inductors 272 are indicated by an interval (distance) Sh.

The distance Dis is 10 μm±5 μm (3σ), for example, 18 μm. For example, the height MIDv is 160 μm, the width Wid is 20 μm, the length Dh is 80 μm and the height LIDv is 80 μm. Among the three sides constituting the inductor 172, the width Wid of one straight side 172ab is the widest. In addition, for example, the length Dh may be 4 times or more of the distance Dis, and may be 4 times or more of the distance Dis and 15 times or less of the distance Dis. For example, the height MIDv may be equal to or greater than the length Dh and equal to or greater than the length Dh and equal to or less than five times the length Dh. For example, the distance Sh may be equal to or greater than ¼ of the length Dh, equal to or greater than ½ of the length Dh, and equal to or less than 2 times the length Dh.

### [1-5. Overview of Inductor Group 171 and Inductor Group 271]

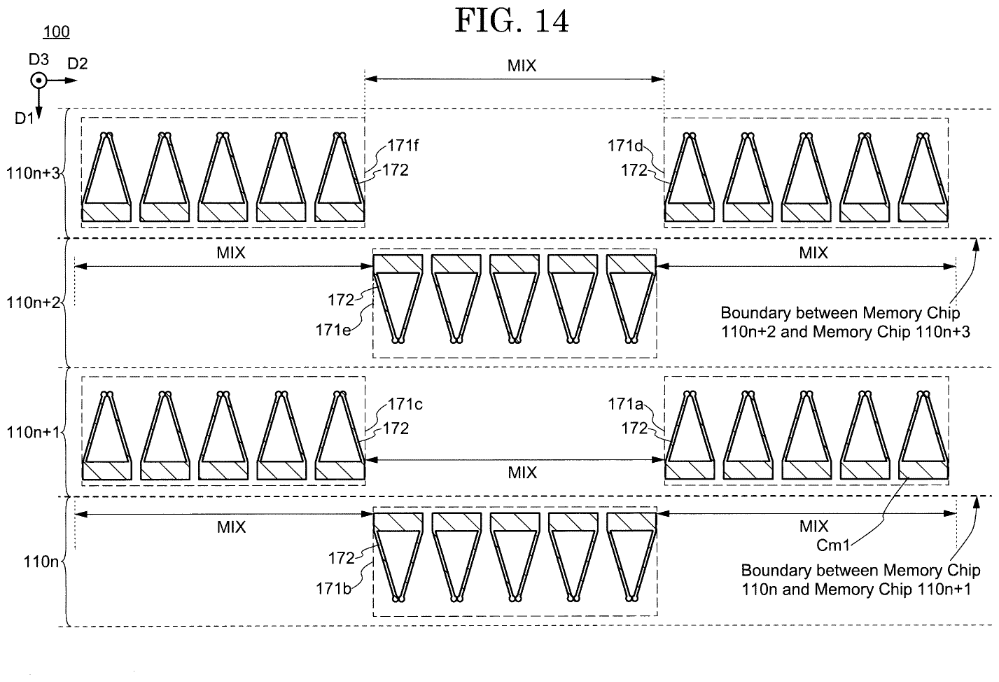

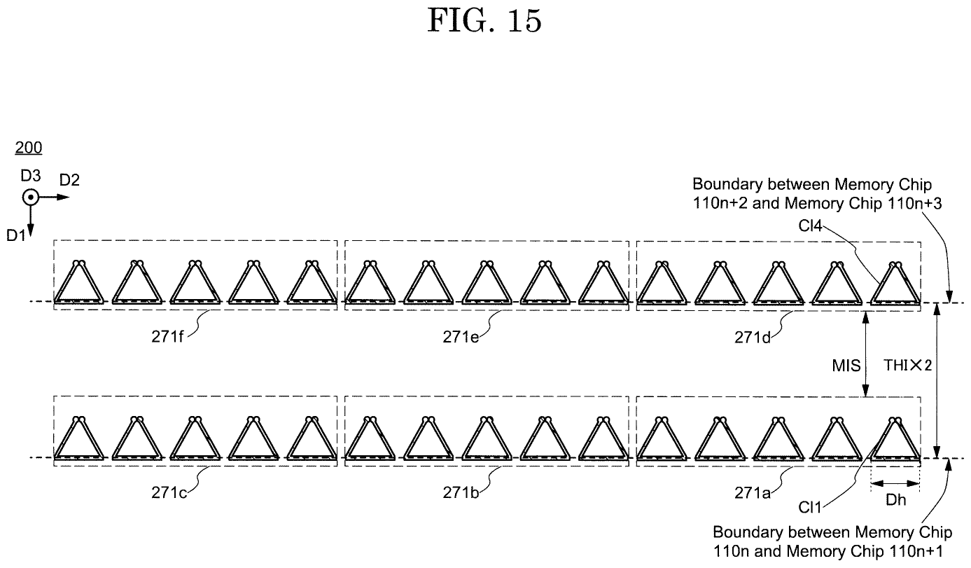

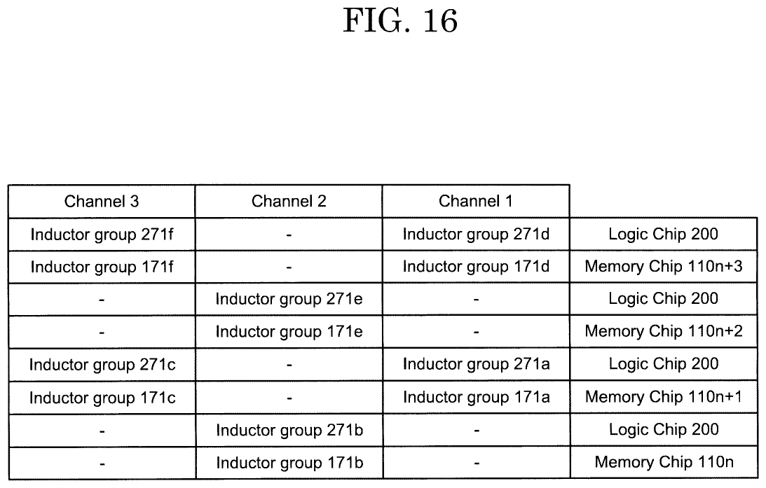

Next, an overview of the inductor group 171 and the inductor group 271 according to the first embodiment will be described with reference to FIG. 14 to FIG. 16. FIG. 14 is a schematic view showing the positional relationship of the inductor group 171 included in each of the plurality of memory chips 110, FIG. 15 is a schematic view showing the positional relationship of the plurality of inductor groups 271, and FIG. 16 is a schematic view showing the relationship between the inductor group 271 included in the logic chip 200 and the memory chip 110 (the inductor group 171 included in the memory chip 110) during inductor communication. The description of the same or similar configurations as those in FIG. 1 to FIG. 13 will be omitted here.

As shown in FIG. 14, for example, the memory cube 100 includes the memory chips 110n to 110n+3 as described in “1-2. Overview of Memory Cube 100”. For example, the memory chip 110n and the memory chip 110n+1 are stacked so that the inductor layers 170 (see FIG. 1) face each other, and the memory chip 110n+2 and the memory chip 110n+3 are stacked so that the inductor layers 170 (see FIG. 1) face each other. In addition, for example, the memory chip 110n+1 and the memory chip 110n+2 are stacked so that the transistor layers 130 (see FIG. 1) face each other.

In order to make the configuration of the inductor groups 171a to 171f easy to see, the inductor groups 171a to 171f shown in FIG. 14 are shown to be parallel to the surface formed in the direction D1 and the direction D2 (the second surface 204 of the logic chip 200). In practice, since the memory chips 110n to 110n+3 are arranged (vertically arranged) in the direction D3 with respect to the second surface 204 of the logic chip 200, the inductor groups 171a to 171f are vertically arranged with respect to the second surface 204 of the logic chip 200.

For example, the memory chip 110n includes the inductor group 171b, the memory chip 110n+1 includes the inductor group 171a and the inductor group 171c, the memory chip 110n+2 includes the inductor group 171e, and the memory chip 110n+3 includes the inductor group 171d and the inductor group 171a. FIG. 14 is an enlarged view of a portion of the memory cube 100, in which each of the memory chips 110n to 110n+3 includes the plurality of inductor groups 171, and the plurality of inductor groups 171 is arranged apart from each other by the length MIX. For example, the inductor group 171a is arranged spaced apart from the inductor group 171, which is not shown, and which is adjacent to the direction D2 in parallel, by the length MIX. Similar to this, the other inductor groups are arranged apart from the inductor group 171, which is not shown, and which is adjacent to the direction D2 in parallel, by the length MIX. In addition, each of the inductor groups 171a to 171f includes a configuration and a function similar to those of the inductor group 171 described with reference to FIG. 8 in “1-2. Overview of the Memory Cube 100”.

In the case where the memory cube 100 is viewed from the direction D3 (that is, a direction perpendicular to the direction D1 and the direction D2, and a direction perpendicular to the second surface 204), the inductor groups 171a to 171f included in the memory chips 110n to 110n+3 are arranged in a checkered pattern.

As shown in FIG. 15, the plurality of inductor groups 271 includes the inductor groups 271a to 271f. The inductor groups 271a to 271f are uniformly arranged in a matrix in the direction D1 and the direction D2. Each of the inductor groups 271a to 271f includes a configuration and a function similar to those of the inductor group 271 described with reference to FIG. 12 in “1-3. Overview of Logic Chip 200”.

For example, one straight side (e.g., a 272ab) of each of the inductor groups 271a, 271b, and 271c is arranged in parallel on the boundary between the memory chip 110n and the memory chip 110n+1. In addition, for example, one straight side (e.g., 272bb) of each of the inductor groups 271d, 271e, and 271f is arranged in parallel on the boundary between the memory chip 110n+2 and the memory chip 110n+3.

For example, in the case where the thickness THI of the memory chips 110n to 110n+3 and the logic chip 200 is 80 μm, the interval (distance) between the boundary between the memory chip 110n and the memory chip 110n+1 and the boundary between the memory chip 110n+2 and the memory chip 110n+3 is 160 μm, which is twice the thickness THI (THI×2). In addition, for example, the length Dh is 70 μm, and an interval MIS (distance MIS) between the inductor group 271a and the inductor group 271d in the direction D1 is 90 μm. Therefore, in the semiconductor module 10 according to the first embodiment, the thickness THI of the memory chips 110n to 110n+3 and the logic chip 200 is thicker (longer) than the length Dh of one straight side of the inductor 172 and the inductor 272.

As shown in FIG. 16, for example, the semiconductor module 10 includes three channels (Channel 1), (Channel 2), and (Channel 3). For example, the memory chip 110n and the memory chip 110n+2 correspond to an even-numbered channel (channel 2), and the memory chip 110n+1 and the memory chip 110n+3 correspond to an odd-numbered channel (channel 1 and channel 3).

The plurality of inductors 272 of the inductor group 271b included in the logic chip 200 communicates with the plurality of inductors 172 of the inductor group 171b included in the corresponding memory chip 110n in a one-to-one manner on the channel 2. In the same manner, the plurality of inductors 272 of the inductor group 271a communicates with the plurality of inductors 172 of the corresponding inductor group 171a one-to-one on the channel 1, the plurality of inductors 272 of the inductor group 271c communicates with the plurality of inductors 172 of the corresponding inductor group 171c one-to-one on the channel 3, the plurality of inductors 272 of the inductor group 271e communicates with the plurality of inductors 172 of the corresponding inductor group 171e one-to-one on the channel 2, the plurality of inductors 272 of the inductor group 271d communicates with the plurality of inductors 172 of the corresponding inductor group 171d one-to-one on the channel 1, and the plurality of inductors 272 of the inductor group 271f communicates with the plurality of inductors 172 of the corresponding inductor group 171f one-to-one on the channel 3.

Since the semiconductor module 10 includes a plurality of channels, it is possible to suppress crosstalk in communication between the memory chip 110n and the memory chip 110n+1 arranged at substantially the same position and the logic chip 200. Similarly, it is possible to suppress crosstalk in communication between the memory chip 110n+2 and the memory chip 110n+3 arranged at substantially the same position and the logic chip 200.

For example, in designing the semiconductor module 10, it is preferable that the interval MIS between the inductor group 271a and the inductor group 271d in the direction D1 is set to be approximately the same length as the length Dh of one straight side of the inductor 172 and the inductor 272. This makes it possible to suppress crosstalk in communication between adjacent inductors. For example, an inductor Cm1 included in the inductor group 171a of the memory chip 110n+1 is capable of inductor communication by magnetic field coupling with an inductor Cl1 included in the inductor group 271a of the logic chip 200, but the inductor Cm1 is not magnetic field coupling with an inductor Cl4 included in the inductor group 271d of the logic chip 200, and does not cross talk. In addition, the inductor Cl1 and the inductor Cl4 are not magnetically coupled and do not cross talk.

### [1-6. Example of Method for Manufacturing Semiconductor Module 10]

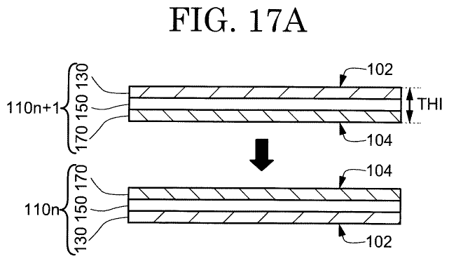

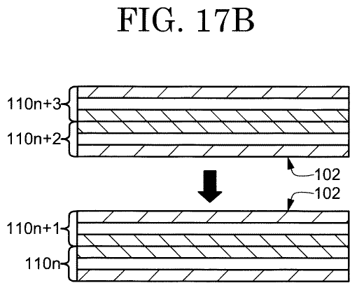

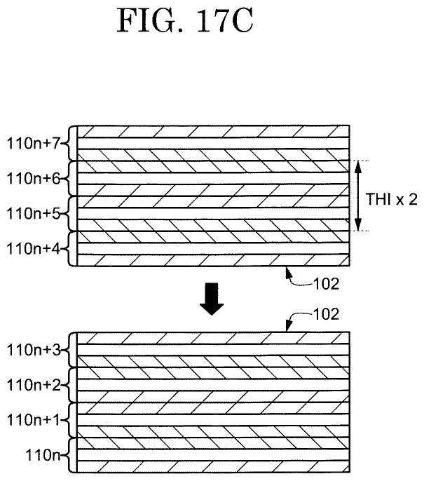

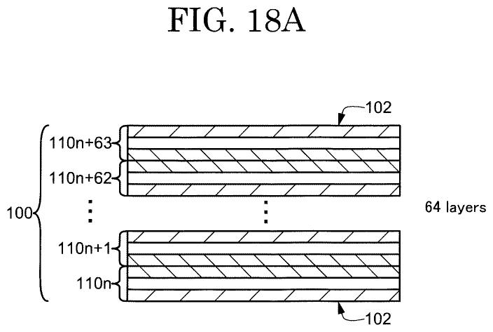

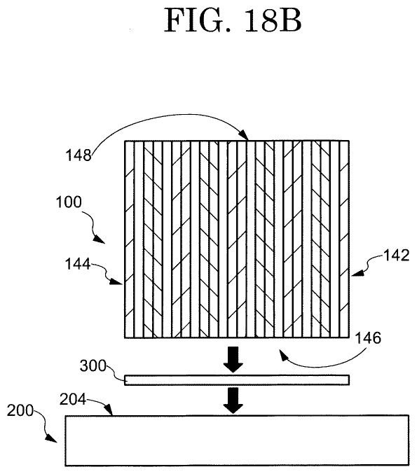

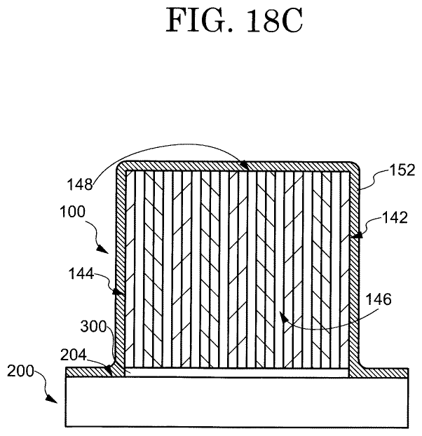

Next, an example of a method for manufacturing the semiconductor module 10 will be mainly described with reference to FIG. 17 and FIG. 18. FIG. 17A to FIG. 17C, and FIG. 18A to FIG. 18C are schematic views showing a method for manufacturing the semiconductor module 10. The description of the same or similar configurations as those in FIG. 1 to FIG. 16 will be omitted here.

For example, stacking (bonding) the memory chips 110 so that the second surfaces 104 on the inductor layer 170 side face each other is referred to as F2F bonding (Face to Face Fusion). For example, stacking (bonding) the memory chips 110 so that the first surfaces 102 on the transistor layer 130 side face each other is referred to as B2B bonding (Back to Back Fusion). For example, stacking (bonding) the memory chips 110 so that the second surfaces 104 on the inductor layer 170 side and the first surfaces 102 on the transistor layer 130 side face each other is referred to as F2B bonding (Face to Back Fusion). For example, a technique such as welding (Fusion Bonding) or silicon direct bonding (SDB) can be used for stacking (bonding) the memory chips. Since welding and silicon direct bonding are techniques used in the technical field, the description will be omitted here.

In step 1, the second surface 104 of the memory chip 110n and the second surface 104 of the memory chip 110n+1 are stacked (bonded) so as to face each other (see FIG. 17A). That is, in step 1, the two memory chips of the memory chip 110n and the memory chip 110n+1 are bonded by the F2F bonding. For example, the thickness THI of the memory chip 110 is 80 μm.

In step 2, the memory chip 110n and the memory chip 110n+1 F2F bonded in step 1 are bonded to the memory chip 110n+2 and the memory chip 110n+3 F2F bonded similar to the memory chip 110n and the memory chip 110n+1 (see FIG. 17B). For example, the first surface 102 of the bonded memory chip 110n and the bonded memory chip 110n+1 on the memory chip+1 side is bonded to the first surface 102 of the bonded memory chip 110n+2 and the bonded memory chip 110n+3 on the memory chip+2 side. That is, the four memory chips 110n to 110n+3 are B2B bonded.

In step 3, the B2B bonded memory chips 110n to 110n+3 in step 2 are B2B bonded to the memory chips 110n+4 to 110n+7 bonded similar to the memory chips 110n to 110n+3 (see FIG. 17C). For example, the first surface 102 on the memory chip 110n+1 side of the bonded memory chips 110n to the memory chipn+3 is bonded to the first surface 102 on the memory chip 110n+2 side of the bonded memory chips 110n+4 to the memory chip 110n+7. That is, the eight memory chips 110n to 110n+7 are B2B bonded. For example, the combined thickness of the two memory chips 110 is 160 μm, which is twice the thickness THI.

By repeating the similar steps as in step 3 from step 4 to step 6, the memory chips 110n to 110n+63 are stacked (bonded) to form the memory cube 100 in which 64 layers of the memory chip 110 are stacked (see FIG. 18A). For example, the first side surface 145, the second side surface 146, the third side surface 147, and the fourth side surface 148 of the memory cube 100 are polished and planarized. For example, chemical mechanical polishing (CMP) can be used for the polishing.

Next, in step 7, the memory cube 100 is arranged on the logic chip 200 using the adhesive layer 300. For example, the second side surface 146 of the memory cube 100 is connected to the adhesive layer 300 and the second side surface 146 and the adhesive layer 300 of the memory cube 100 are adhered onto the second surface 204 of the logic chip 200 (see FIG. 18B). For example, the adhesive layer 300 may be an adhesive including an epoxy resin, an acrylic polymer, or the like, a die bonding film including an epoxy resin or an acrylic polymer, or an adhesive film such as a die attached film.

Next, in step 8, a heat dissipation layer 152 is stacked so as to be in contact with the second surface 204 of the logic chip 200 on which the adhesive layer 300 is not arranged, and in contact with the first surface 142 and the second surface 144 of the memory cube 100, and the fourth side surface 148 of the memory cube 100 (refer to 18C of the drawings). The fourth side surface 148 is opposite the second side surface 146 with respect to the direction D3. In addition, the heat dissipation layer 152 may be referred to as a heat sink.

For example, the thickness THI of the plurality of memory chips 110 can be processed with an accuracy of the thickness THI±1.3 μm (3σ). In addition, for example, the position of the inductor 172 is the design value ±4 μm (3σ) in the memory cube 100 in which 64 layers of the memory chip 110 are stacked. Further, the alignment accuracy of the chip bonder that mounts the memory cube 100 on the logic chip 200 is a design value of ±2 μm (3σ). Therefore, for example, the horizontal position of the inductor 172 (for example, one straight side 172ab) at the time of mounting is ±4.5 μm (3σ). In addition, for example, when the distance Dis between the inductor 172 and the inductor 272 is the design value of 10 μm, and the variation ±4.5 μm in the horizontal position of the inductor 172 (for example, one straight side 172ab) at the time of mounting is considered, the length Dh of one straight side 172ab and 272ab of the inductor is designed so as to be capable of inductor communication even if the distance Dis is 11 μm.

[1-7. Comparison Between Semiconductor Module 10 and Semiconductor Module 500 according to Comparative Example]

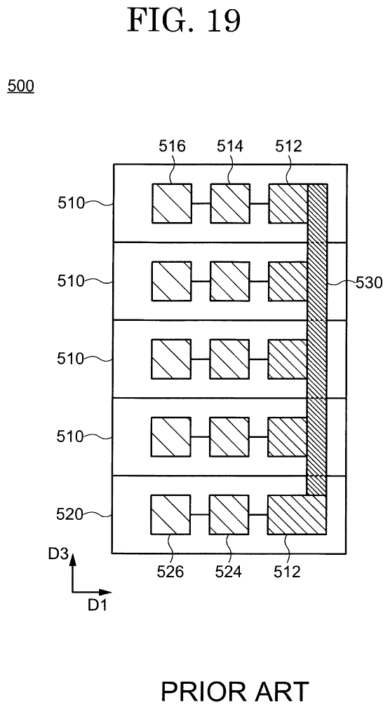

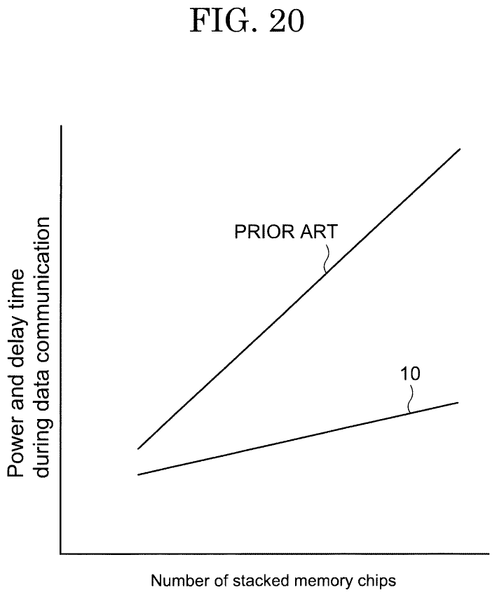

Next, a comparison between the semiconductor module 10 and the semiconductor module 500 according to the comparative example will be mainly described with reference to FIG. 1, FIG. 2, FIG. 19, and FIG. 20. FIG. 19 is a schematic view showing a configuration of a semiconductor module according to the comparative example, and FIG. 20 is a graph showing power and delay times during data communication with respect to the number of stacked memory chips of the semiconductor module 10 and the semiconductor module 500 according to the comparative example (PRIOR ART). The description of the same or similar configurations as those in FIGS. 1 to 18 will be omitted here.

As shown in FIG. 19, the semiconductor module 500 according to the comparative example includes a configuration in which a plurality of memory chips 510 and a plurality of logic chips 520 are stacked in the direction D3. Each of the plurality of memory chips 510 includes a protection circuit 512, an interface 514 electrically connected to the protection circuit 512, and a memory module 516 electrically connected to the interface 514. The logic chip 520 includes the protection circuit 512, an interface 524 electrically connected to the protection circuit 512, and a logic module 526 electrically connected to the interface 524. The protection circuit 512 included in the plurality of memory chips 510 and the protection circuit 512 included in the logic chip 520 are connected using a through electrode 530 formed in the direction D3. For example, in the semiconductor module 500, the plurality of memory chips 510 is connected by the through electrode 530 using copper (Cu).

That is, as shown in FIG. 20, in the semiconductor module 500, since the length of the through electrode 530 increases in proportion to the number of stacked memory chips 510, the wiring resistance and the parasitic capacitance such as the wiring capacitance associated with the through electrode 530 increase. As a result, in the semiconductor module 500, the power at the time of data communication and the delay time required for communication increase in proportion to the number of stacked memory chips 510. In addition, for example, in the semiconductor module 500, the amount of noise such as power supply noise (switching noise) also increases.

On the other hand, in the semiconductor module 10, the distance between the plurality of inductors 172 included in the memory cube 100 and the inductor 272 included in the corresponding logic chip 200 in a one-to-one manner is substantially the same due to the corresponding inductor 172 and the inductor 272 in a one-to-one manner, and the corresponding inductor 172 and the inductor 272 in a one-to-one manner can communicate with each other in a non-contact manner. Therefore, the wiring capacitance of the semiconductor module 10 and the parasitic capacitance such as the wiring capacitance can be smaller than that of the semiconductor module 500. Therefore, as shown in FIG. 20, the semiconductor module 10 consumes less power and is capable of higher-speed communication than the semiconductor module 500. In addition, the semiconductor module 10 can also reduce the amount of noise such as power supply noise (switching noise) from the semiconductor module 500.

### Second Embodiment

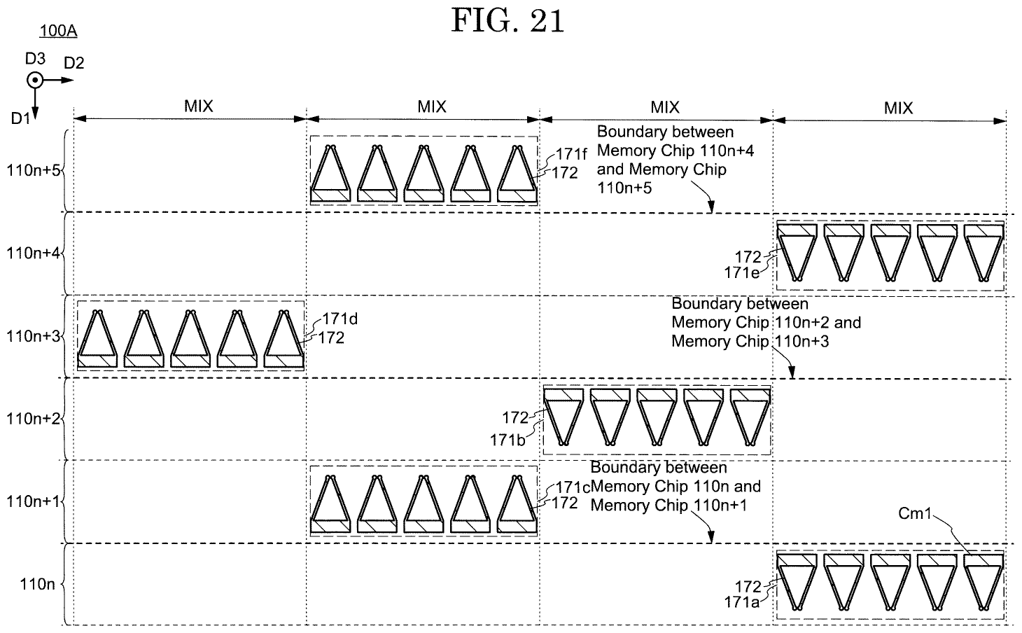

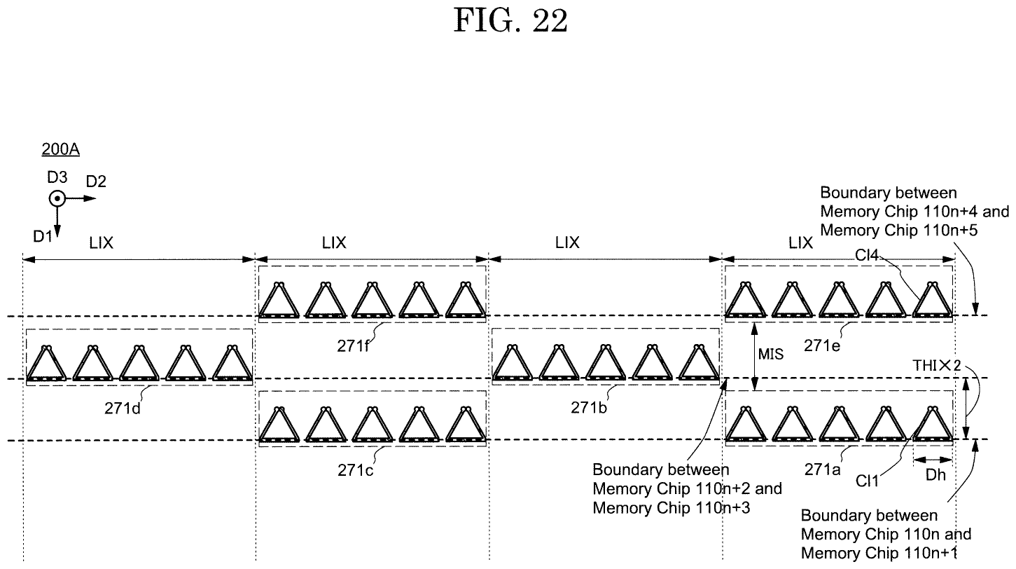

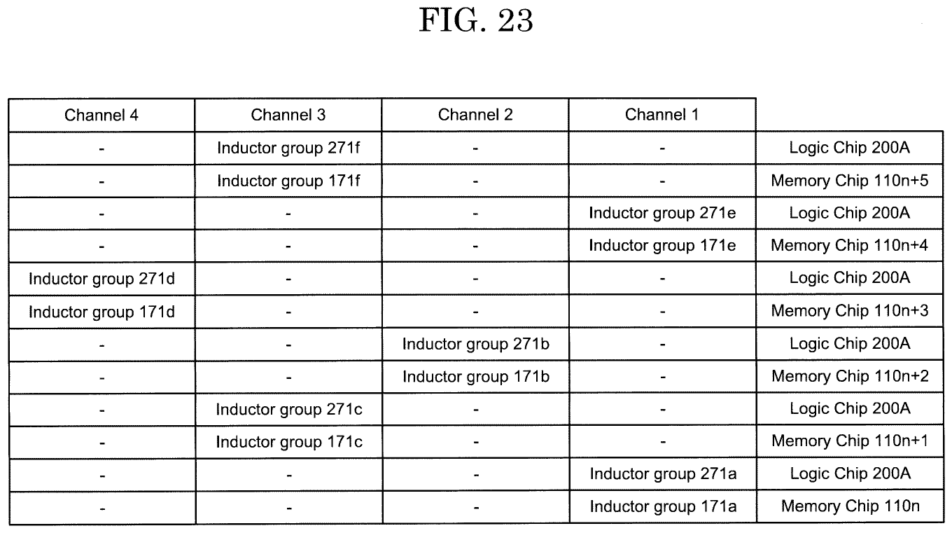

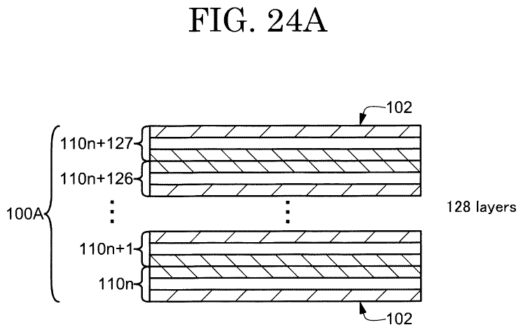

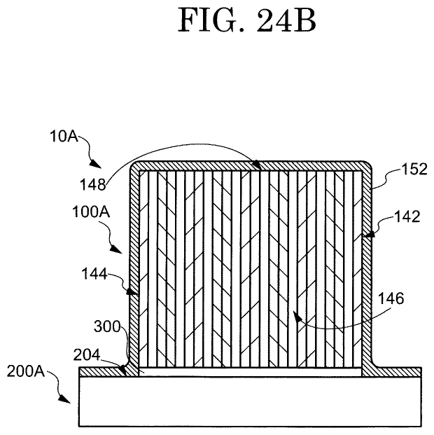

A semiconductor module 10A according to the second embodiment will be described with reference to FIG. 21 to FIG. 24B. FIG. 21 is a schematic view showing the positional relationship between the inductor group 171 included in each of the plurality of memory chips 110 according to the second embodiment, FIG. 22 is a schematic view showing the positional relationship between the inductor group 271 included in a logic chip 200A according to the second embodiment of the present invention, FIG. 23 is a schematic view showing the relationship between the inductor group 271 included in the logic chip 200A during inductor communication according to the second embodiment of the present invention and the memory chip 110 (inductor group 171 included in the memory chip), and FIG. 24A and FIG. 24B are schematic views showing a method for manufacturing the semiconductor module 10A according to the second embodiment of the present invention. The description of the same or similar configurations as those in FIG. 1 to FIG. 20 will be omitted here.

### [2-1. Summary of Semiconductor Module 10A]

As shown in FIG. 21, FIG. 22, FIG. 23, FIG. 24A, or FIG. 24B, the semiconductor module 10A includes a memory cube 100A and a logic chip 200A.

The memory cube 100A includes 128 layers of the memory chip 110, while the memory cube 100 includes 64 layers of the memory chip 110. In addition, although details will be described later, the arrangement of the inductor group 171 of the memory cube 100A and the inductor group 271 of the logic chip 200A is different from the arrangement of the inductor group 171 of the memory cube 100 and the inductor group 271 of the logic chip 200. Since the other functions and configurations of the memory cube 100A and the logic chip 200A are similar to those of the memory cube 100 and the logic chip 200, the description will be omitted here.

For example, the memory cube 100 includes a configuration similar to the configuration described in “1-2. Overview of Memory Cube 100”. For example, the memory cube 100 includes the memory chips 110n to 110n+5. The memory chip 110n and the memory chip 110n+1, the memory chip 110n+2 and the memory chip 110n+3, and the memory chip 110n+4 and the memory chip 110n+5 are stacked so that their inductor layers 170 (see FIG. 1) face each other. In addition, the memory chip 110n+1 and the memory chip 110n+2, and the memory chip 110n+3 and the memory chip 110n+4 are stacked so that their transistor layers 130 (see FIG. 1) face each other.

In order to make the configuration of the inductor groups 171a to 171f easy to see, similar to FIG. 14, the inductor groups 171a to 171f shown in FIG. 21 are shown to be parallel to the surface formed in the direction D1 and the direction D2 (the second surface 204 of the logic chip 200).

The memory chip 110n includes the inductor group 171a, the memory chip 110n+1 includes the inductor group 171c, the memory chip 110n+2 includes the inductor group 171b, the memory chip 110n+3 includes the inductor group 171d, the memory chip 110n+4 includes the inductor group 171e, and the memory chip 110n+5 includes the inductor group 171f. FIG. 21 is an enlarged view of a part of the memory cube 100A.

Each of the memory chips 110n to 110n+5 includes the plurality of inductor groups 171, and the plurality of inductor groups 171 in the same memory chip 110 is arranged in the direction D2 at a distance three times the length LIX from each other. For example, the inductor group 171a is arranged at a distance three times the length MIX from the inductor group 171 adjacent to the direction D2 in parallel (not shown). The other inductor groups are also arranged at a distance three times the length MIX from the inductor group 171 adjacent to the direction D2 in parallel (not shown).

In the memory chip 110 in which the inductor layers 170 (the second surface 104) are stacked (bonded) so as to face each other, the inductor groups 171 are arranged at a distance of the length MIX from each other. For example, the inductor group 171a included in the memory chip 110n is arranged at a distance from the inductor group 171c included in the memory chip 110n+1 by the length MIX. Similar to the memory chip 110n and the memory chip 110n+1, the same applies to the inductor groups included in the memory chips 110n+2 to 110n+5.

In addition, each of the inductor groups 171a to 171f includes similar configurations and functions as those of the inductor group 171 described with respect to FIG. 8 in “1-2. Overview of Memory Cube 100”.

As shown in FIG. 22, the plurality of inductor groups 271 includes the inductor groups 271a to 271f. The inductor groups 271a to 271f are arranged in a checkered pattern in the direction D1 and the direction D2. Each of the inductor groups 271a to 271f includes similar configurations and functions as those of the inductor group 271 described with reference to FIG. 12 in “1-3. Overview of Logic Chip 200”.

For example, one straight side (e.g., 272ab) of each of the inductor groups 271a and 271c is arranged in parallel on the boundary between the memory chip 110n and the memory chip 110n+1. For example, one straight side (e.g., a 272ab) of each of the inductor groups 271b and 271d is arranged in parallel on the boundary between the memory chip 110n+2 and the memory chip 110n+3. In addition, for example, one straight side (e.g., 272bb) of each of the inductor groups 271e and 271f are arranged in parallel on the boundary between the memory chip 110n+4 and the memory chip 110n+5.

For example, in the case where the thickness THI of the memory chips 110n to 110n+5 and the logic chip 200 is 40 μm, the interval (distance) between the boundary between the memory chip 110n and the memory chip 110n+1 and the boundary between the memory chip 110n+2 and the memory chip 110n+3) is 80 μm, which is twice the thickness THI (THI×2).

Similarly, the interval (distance) between the boundary between the memory chip 110n+2 and the memory chip 110n+3 and the boundary between the memory chip 110n+4 and the memory chip 110n+5 (distance) is 80 μm, which is twice the thickness THI (THI×2).

In addition, for example, the length Dh is 70 μm, and the interval MIS (distance MIS) between the inductor group 271a and the inductor group 271e in the direction D1 is 80 μm. Therefore, in the semiconductor module 10 according to the second embodiment, the thickness THI (40 μm) of the memory chips 110n to 110n+5 and the logic chip 200 is thinner (shorter) than the length Dh (70 μm) of one straight side of the inductor 172 and the inductor 272.

As shown in FIG. 23, for example, the semiconductor module 10A includes four channels (Channel 1, Channel 2, Channel 3, and Channel 4). For example, the memory chip 110n and the memory chip 110n+4 correspond to the channel 1, the memory chip 110n+2 corresponds to the channel 2, the memory chip 110n+1 and the memory chip 110n+5 correspond to the channel 3, and the memory chip 110n+3 corresponds to the channel 4.

Similarly, the plurality of inductors 272 of the inductor group 271a included in the logic chip 200A communicates with the plurality of inductors 172 of the inductor group 171a included in the corresponding memory chip 110n in a one-to-one manner on the channel 1. The plurality of inductors 272 of the inductor group 271b included in the logic chip 200A communicates with the plurality of inductors 172 of the inductor group 171b included in the corresponding memory chip 110n+2 one-to-one on the channel 2, the plurality of inductors 272 of the inductor group 271c included in the logic chip 200A communicates with the plurality of inductors 172 of the inductor group 171c included in the corresponding memory chip 110n+1 one-to-one on the channel 3, the plurality of inductors 272 of the inductor group 271d included in the logic chip 200A communicates with the plurality of inductors 172 of the inductor group 171d included in the corresponding memory chip 110n+3 one-to-one on the channel 4, the plurality of inductors 272 of the inductor group 271e included in the logic chip 200A communicates with the plurality of inductors 172 of the inductor group 171e included in the corresponding memory chip 110n+4 one-to-one on the channel 1, and the plurality of inductors 272 of the inductor group 271f included in the logic chip 200A communicates with the plurality of inductors 172 of the inductor group 171f included in the corresponding memory chip 110n+5 one-to-one on the channel 3.

The semiconductor module 10A includes the plurality of channels, making it possible to suppress crosstalk in communication between the memory chip 110 and the logic chip 200.

For example, the thickness THI of the plurality of memory chips 110 can be processed with an accuracy of the thickness THI±1.3 μm (3σ). Furthermore, for example, in the design of the semiconductor module 10A, the position of the inductor 172 is the design value ±6 μm (3σ) in the memory cube 100 in which the 128-layer memory chip 110 is stacked. For example, the interval MIS between the inductor group 271a and the inductor group 271e in the direction D1 is preferably set to be approximately the same length as the length Dh of one straight side of the inductor 172 and the inductor 272. This makes it possible to suppress crosstalk in communication between adjacent inductors. For example, the inductor Cm1 included in the inductor group 171a of the memory chip 110n is capable of inductor communication by magnetic field coupling with the inductor Cl1 included in the inductor group 271a of the logic chip 200A, but the inductor Cm1 is not magnetic field coupling with the inductor Cl4 included in the inductor group 271e of the logic chip 200A and does not cross talk. In addition, the inductor Cl1 and the inductor Cl4 are not magnetically coupled and do not cross talk.

### [2-2. Example of Method for Manufacturing Semiconductor Module 10A]

Next, an example of a method for manufacturing the semiconductor module 10A will be mainly described with reference to FIG. 24. FIG. 24A and FIG. 24B are schematic view showing the method for manufacturing the semiconductor module 10A. The description of the same or similar configurations as those in FIG. 1 to FIG. 23 will be omitted here.

In the method for manufacturing the semiconductor module 10A, similar to the manufacturing method described with reference to FIG. 17A to FIG. 17C and FIG. 18A in “1-6. Example of Method for Manufacturing Semiconductor Module 10”, steps 1 to 6 are executed to stack 64 layers of the memory chip 110. Subsequently, in step 9, the memory cube 100A in which 128 layers of the memory chip 110 are stacked is formed by B2B bonding two blocks in which 64 layers of the memory chip 110 are stacked (see FIG. 1 and FIG. 24A).

Next, in step 10, similar to step 7 and step 8 described with reference to FIG. 18B and FIG. 18C in “1-6. Example of Method for Manufacturing Semiconductor Module 10”, the memory cube 100A is arranged on the logic chip 200A using the adhesive layer 300, and the heat dissipation layer 152 is stacked (see FIG. 24B).

### Third Embodiment

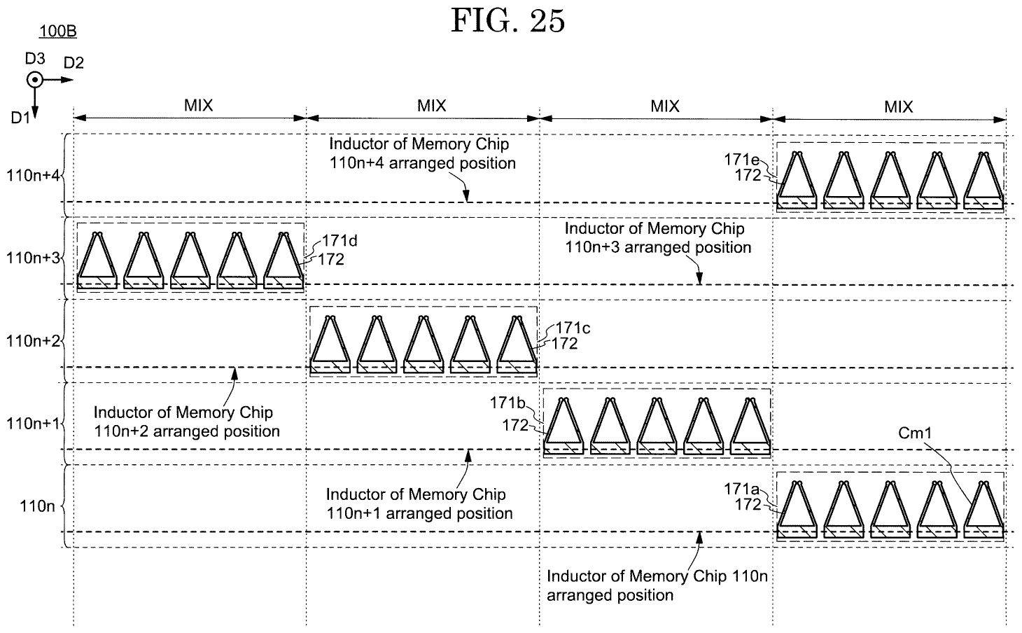

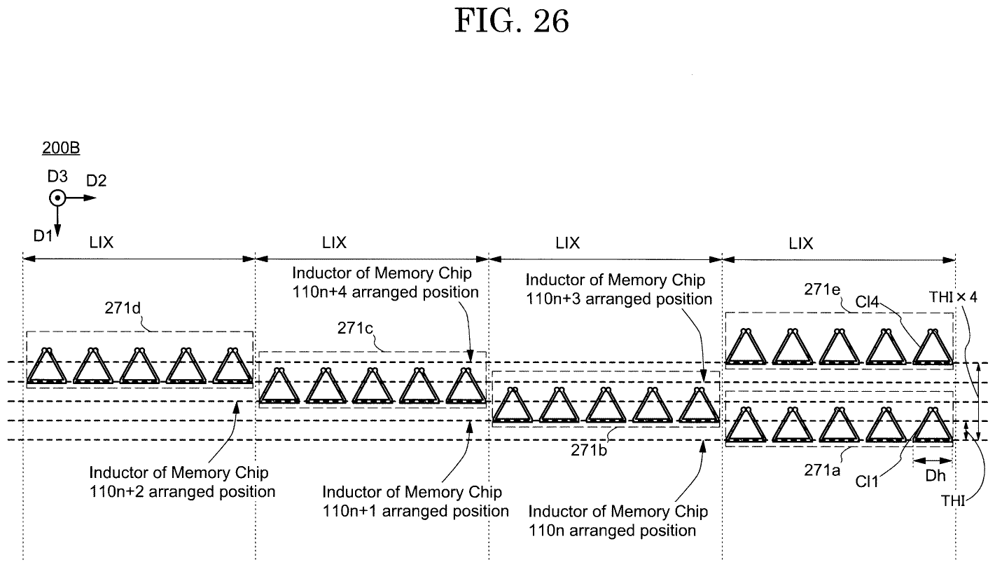

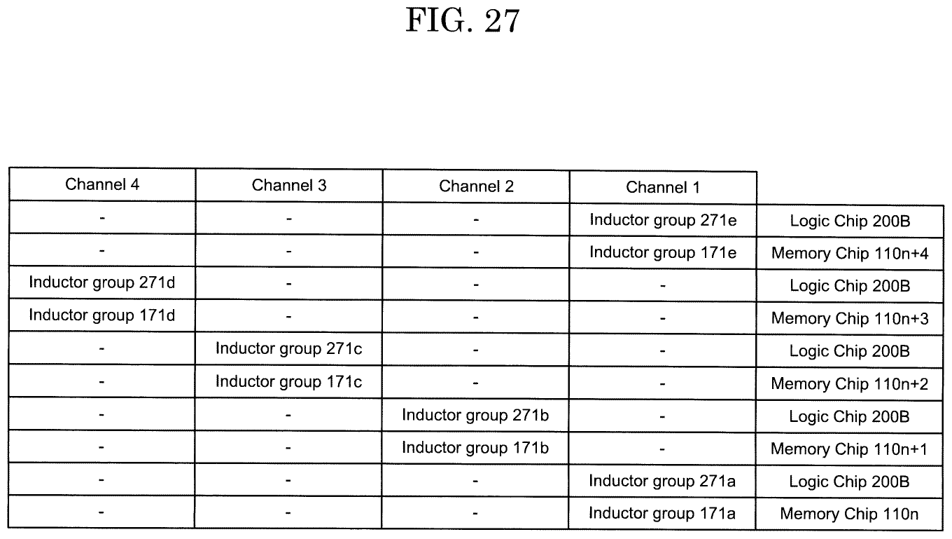

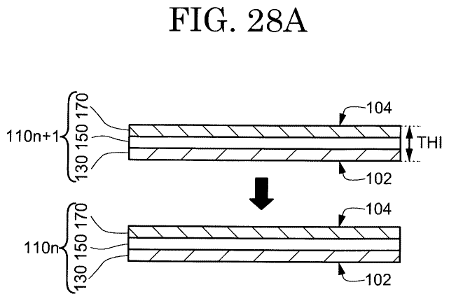

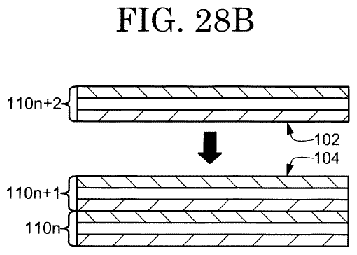

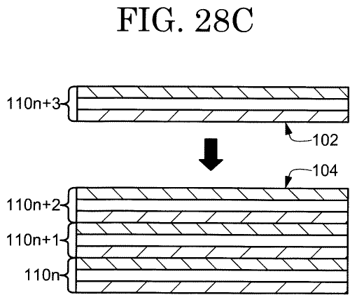

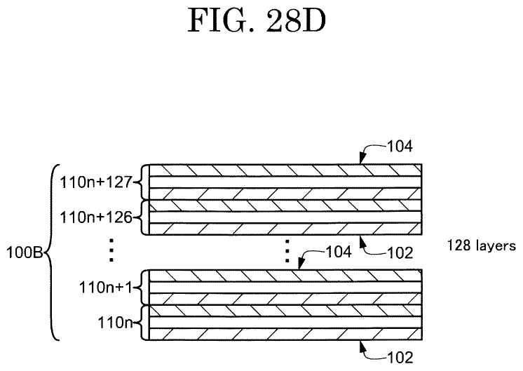

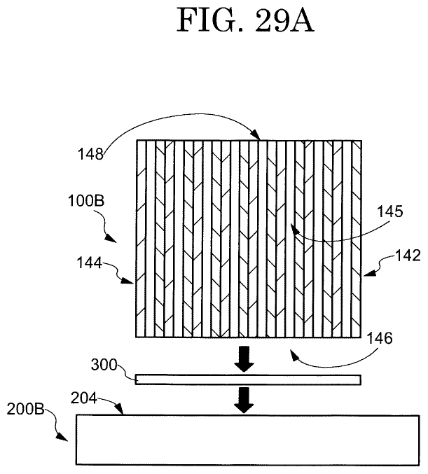

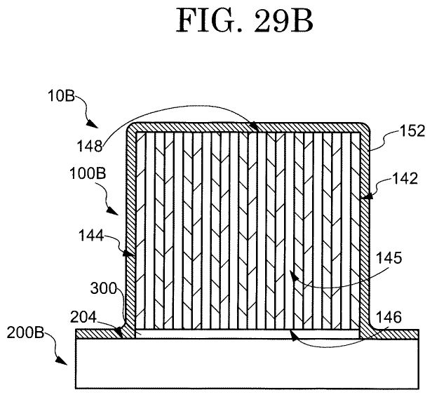

A semiconductor module 10B according to the third embodiment will be described with reference to FIG. 25 to FIG. 29B. FIG. 25 is a schematic view showing the positional relationship of the inductor group 171 included in each of the plurality of memory chips 110 according to the third embodiment of the present invention, FIG. 26 is a schematic view showing the positional relationship of the inductor group 271 included in a logic chip 200B according to the third embodiment of the present invention, FIG. 27 is a schematic view showing the relationship between the inductor group 271 and the memory chip 110 included in the logic chip 200B (the inductor 171 included in the memory chip) during inductor communication according to the third embodiment of the present invention, and FIG. 28A to FIG. 28D, FIG. 29A and FIG. 29B show the method for manufacturing the semiconductor module 10B according to the third embodiment of the present invention. The description of the same or similar configurations as those in FIG. 1 to FIG. 24 will be omitted here.

### [3-1. Overview of Semiconductor Module 10B]

As shown in FIG. 25, FIG. 26, FIG. 29A, or FIG. 29B, the semiconductor module 10B includes a memory cube 100B and the logic chip 200B.

Similar to the memory cube 100A, the memory cube 100B includes 128 layers of the memory chip 110. Although details will be described later, the arrangement of the inductor group 171 of the memory cube 100B and the inductor group 271 of the logic chip 200B is different from the arrangement of the inductor group 171 of the memory cube 100 and the inductor group 271 of the logic chip 200. Since the other functions and configurations of the memory cube 100B and the logic chip 200B are similar to those of the memory cube 100 and the logic chip 200, the description will be omitted here.

For example, the memory cube 100B includes a configuration similar to the configuration described in “1-2. Overview of Memory Cube 100”. For example, the memory cube 100 includes the memory chips 110n to 110n+4. For example, the memory chip 110n and the memory chip 110n+1, the memory chip 110n+1 and the memory chip 110n+2, the memory chip 110n+2 and the memory chip 110n+3, and the memory chip 110n+3 and the memory chip 110n+4 are stacked so that the inductor layer 170 and the transistor layer 130 face each other.

In order to make the configuration of the inductor groups 171a to 171e easy to see, similar to FIG. 14, the inductor groups 171a to 171e shown in FIG. 21 are shown to be parallel to the surface (the second surface 204 of the logic chip 200) formed in the direction D1 and the direction D2.

The memory chip 110n includes the inductor group 171a, the memory chip 110n+1 includes the inductor group 171b, the memory chip 110n+2 includes the inductor group 171c, the memory chip 110n+3 includes the inductor group 171d, and the memory chip 110n+4 includes the inductor group 171e. FIG. 25 is an enlarged view of a part of the memory cube 100B.

Similar to FIG. 21, each of the memory chips 110n to 110n+4 includes the plurality of inductor groups 171, and the plurality of inductor groups 171 in the same memory chip 110 is arranged in the direction D2 at a distance of three times the length LIX from each other. In addition, each of the inductor groups 171a to 171e includes similar configurations and functions as those of the inductor group 171 described with respect to FIG. 8 in “1-2. Overview of Memory Cube 100”.

As shown in FIG. 26, the plurality of inductor groups 271 includes the inductor groups 271a to 271e. The inductor group 271b is arranged so that the inductor group 271a is arranged at a distance of the length LIX in the direction D1 and at a distance of the thickness THI (40 μm) in the direction D2. Similar to the inductor group 271b, the inductor group 271c is arranged so that the inductor group 271b is arranged in the length LIX in the direction D2 and at a distance of the thickness THI (40 μm) in the direction D1. Similar to the inductor group 271c, the inductor group 271d is arranged so that the inductor group 271c is arranged at a distance of the length LIX in the in direction D2 and at a distance of the thickness THI (40 μm) in the direction D1. The inductor group 271e is arranged so that the inductor group 271a is separated by four times the thickness THI (40 μm) in the direction D1. In addition, each of the inductor groups 271a to 271e includes similar configurations and functions as those of the inductor group 271 described with reference to FIG. 12 in “1-3. Overview of Logic Chip 200”.

One straight side (e.g., 272ab) of the inductor group 271a is arranged in parallel on the position where the inductor 272a of the memory chip 110n is arranged. Similar to the inductor group 271a, one straight side of the inductor group 271b (e.g., 272ab) is arranged in parallel on the position where the inductor 272b of the memory chip 110n+1 is arranged, one straight side of the inductor group 271c (e.g., 272ab) is arranged in parallel on the position where the inductor 272c of the memory chip 110n+2 is arranged, one straight side of the inductor group 271d (e.g., 272ab) is arranged in parallel on the position where the inductor 272c of the memory chip 110n+3 is arranged, and one straight side of the inductor group 271e (e.g., 272ab) is arranged in parallel on the position where the inductor 272e of the memory chip 110n+4 is arranged.

For example, the thickness THI is 40 μm, the length Dh is 70 μm and the interval MIS (distance MIS) between the inductor group 271a and the inductor group 271e in the direction D1 is 80 μm. Therefore, in the semiconductor module 10B according to the third embodiment, the thickness THI (40 μm) of the memory chips 110n to 110n+4 and the logic chip 200 is thinner (shorter) than the length Dh (70 μm) of one straight side of the inductor 172 and the inductor 272.

As shown in FIG. 27, for example, similar to the semiconductor module 10A, the semiconductor module 10B includes four channels (Channel 1, Channel 2, Channel 3, and Channel 4). The memory chip 110n and the memory chip 110n+4 correspond to the channel 1, the memory chip 110n+1 corresponds to the channel 2, the memory chip 110n+2 corresponds to the channel 3, and the memory chip 110n+3 corresponds to the channel 4.

The plurality of inductors 272 of the inductor group 271a included in the logic chip 200B communicates with the plurality of inductors 172 of the inductor group 171a included in the corresponding memory chip 110n in a one-to-one manner on the channel 1. The plurality of inductors 272 of the inductor group 271b included in the logic chip 200B communicates with the plurality of inductors 172 of the inductor group 171b included in the corresponding memory chip 110n+1 one-to-one on the channel 2, the plurality of inductors 272 of the inductor group 271c included in the logic chip 200B communicates with the plurality of inductors 172 of the inductor group 171c included in the corresponding memory chip 110n+2 one-to-one on the channel 3, the plurality of inductors 272 of the inductor group 271d included in the logic chip 200B communicates with the plurality of inductors 172 of the inductor group 171d included in the corresponding memory chip 110n+3 one-to-one on the channel 4, and the plurality of inductors 272 of the inductor group 271e included in the logic chip 200B communicates with the plurality of inductors 172 of the inductor group 171e included in the corresponding memory chip 110n one-to-one on the channel 1.

The semiconductor module 10B includes the plurality of channels, making it possible to suppress crosstalk in communication between the memory chip 110 and the logic chip 200B.

### [2-2. Example of Method for Manufacturing Semiconductor Module 10B]

Next, an example of the method for manufacturing the semiconductor module 10B will be mainly described with reference to FIG. 28A to FIG. 28D, FIG. 29A, and FIG. 29B. FIG. 28A to FIG. 28D, FIG. 29A and FIG. 29B are schematic views showing the method for manufacturing the semiconductor module 10B. The description of the same or similar configurations as those in FIG. 1 to FIG. 27 will be omitted here.

In step 21, the second surface 104 of the memory chip 110n and the first surface 102 of the memory chip 110n+1 are F2B bonded so as to face each other (see FIG. 28A). For example, the thickness THI of the memory chip 110 is 40 μm.

In step 22, F2B bonding is performed so that the second surface 104 of the memory chip 110n+1 side of the memory chip 110n and the memory chip 110n+1 F2B bonded in step 21 faces the first surface 102 of the memory chip 110n+2 (see FIG. 28B).

In step 23, the second surface 104 of the memory chip 110n+2 F2B bonded in step 22 is F2B bonded to the first surface 102 of the memory chip 110n+3 (see FIG. 28C).

By repeating the similar steps as step 23 124 times, the memory chips 110n to 110n+127 are stacked (bonded) by F2B bonding the chips to each other to form the memory cube 100B in which the 128 layers of the memory chip 110 are stacked (see FIG. 28D). Similar to the memory cube 100, for example, the first side surface 145, the second side surface 146, the third side surface 147 (not shown), and the fourth side surface 148 of the memory cube 100B are polished and planarized.

Next, similar to the memory cube 100, the memory cube 100B is arranged on the logic chip 200B using the adhesive layer 300, and the heat dissipation layer 152 is stacked so that the memory cube 100B is in contact with the second surface 204 of the logic chip 200B where the adhesive layer 300 is not arranged, the first surface 142 and the second surface 144 of the memory cube 100, and the fourth side surface 148 of the memory cube 100B (see FIG. 29B).

### Fourth Embodiment

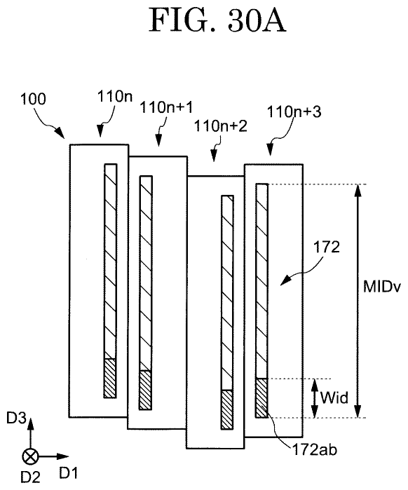

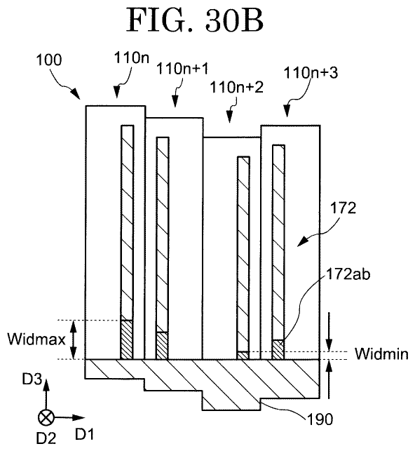

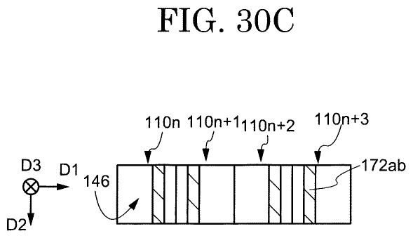

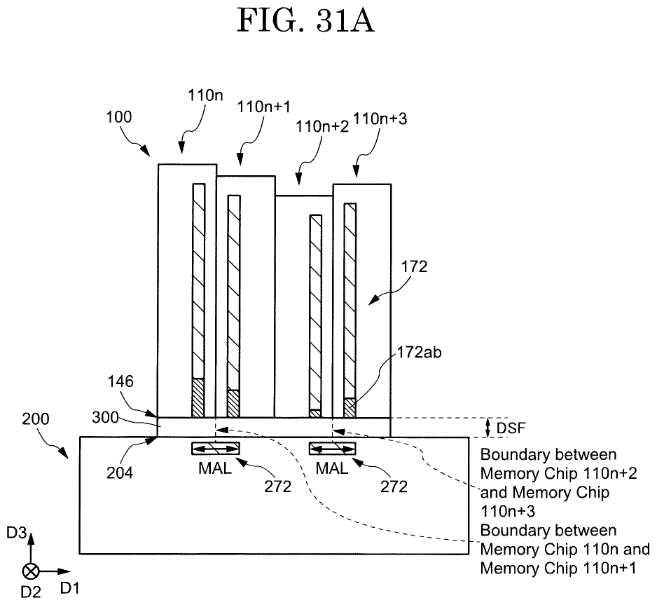

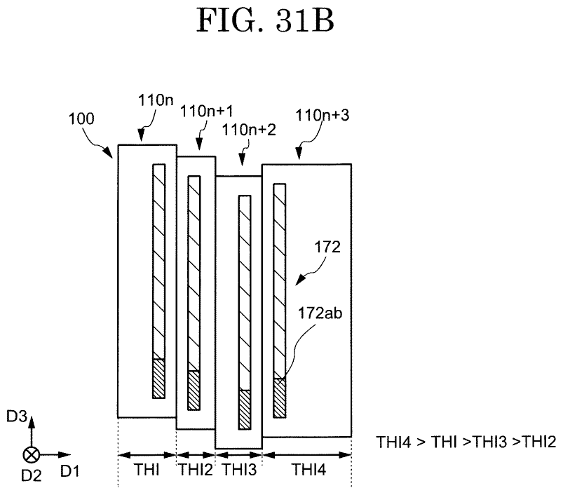

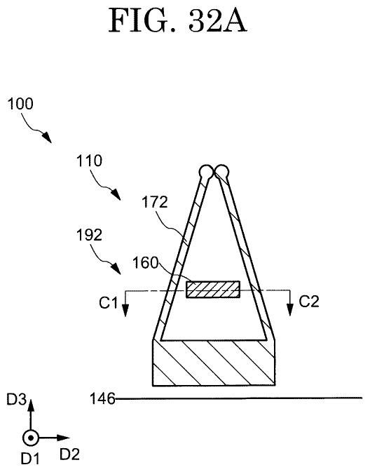

In the fourth embodiment, an example of the method for manufacturing the semiconductor module 10 will be described with reference to FIG. 30A and FIG. 31B. FIG. 30A, FIG. 30B, and FIG. 30C, and FIG. 31A and FIG. 31B are schematic diagrams showing a method for manufacturing a semiconductor module according to the fourth embodiment of the present invention. The descriptions of the same or similar configurations as those in FIG. 1 to FIG. 29B will be omitted here.

For example, the memory cube 100 includes the memory chips 110n to 110n+3, and has a configuration similar to the configuration described in “1-6. Example of Method for Manufacturing Semiconductor Module 10”. That is, the memory chip 110n and the memory chip 110n+1 are F2F connected, the memory chip 110n+2 and the memory chip 110n+3 are F2F connected, and the memory chip 110n+1 and the memory chip 110n+2 are B2B connected.

As shown in FIG. 30A, when the memory chips 110n to 110n+3 are stacked, the positions of the memory chips 110n to 110n+3 corresponding to the second side surface 146 of the memory cube 100 in the direction D3 vary. For example, the height MIDv of the inductor 172 is 160 μm, and the width Wid of one straight side 172ab of the inductor 172 is 20 μm.

As shown in FIG. 30B, when the memory chips 110n to 110n+3 are stacked, for example, an end portion (polished portion 190) of the memory chips 110n to 110n+3 corresponding to the second side surface 146 is polished so that the second side surface 146 of the memory cube 100 is flat.

When the second side surface 146 of the memory cube 100 is polished to be flat, one straight side 172ab is exposed to the second side surface 146 (see FIG. 30C).

As shown in FIG. 31A, the second side surface 146 of the memory cube 100 is arranged so as to be in contact with the adhesive layer 300 with one straight side 172ab exposed to the second side surface 146, and the memory cube 100 and the adhesive layer 300 are arranged on the second side surface 204 of the logic chip 200.

For example, the alignment accuracy MAL between the memory cube 100 and the logic chip 200 is, +5 μm with respect to the boundary between the memory chip 110n and the memory chip 110n+1 (the boundary between the memory chip 110n+2 and the memory chip 110n+3).

A distance DSF between the plurality of straight sides 172ab and the second surface 204 is substantially the same. The distance DFS is the same as the thickness of the adhesive layer 300 and the distance Dis. For example, the distance DFS is 15 μm or more and 20 μm or less.

In addition, as shown in FIG. 31B, for example, the memory cube 100 may be formed by the plurality of memory chips 110n to 110n+3 having a different thickness THI. For example, a thickness THI4 of the memory chip 110n+3 is thicker than the thickness THI of the memory chip 110n, the thickness THI of the memory chip 110n is thicker than a thickness THI3 of the memory chip 110n+2, and the thickness THI3 of the memory chip 110n+2 is thicker than a thickness THI2 of the memory chip 110n+2.

### Fifth Embodiment

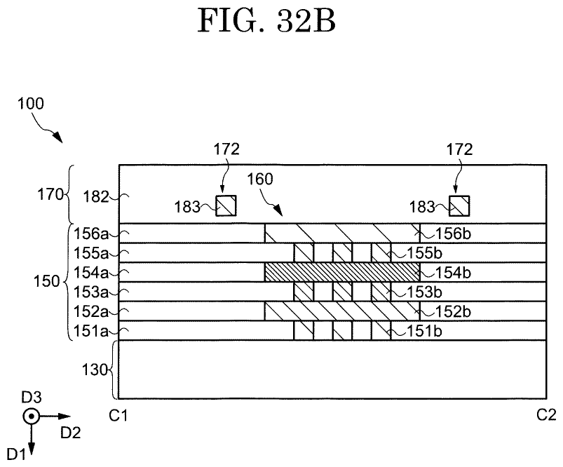

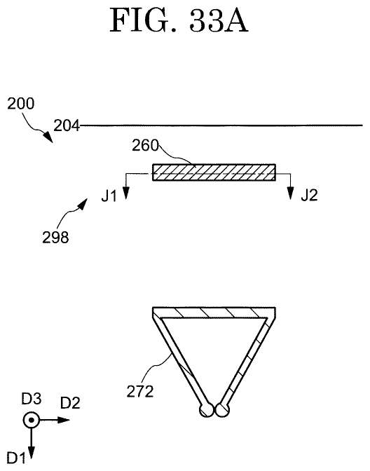

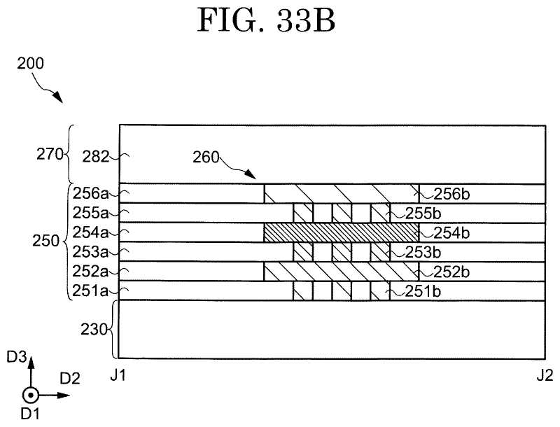

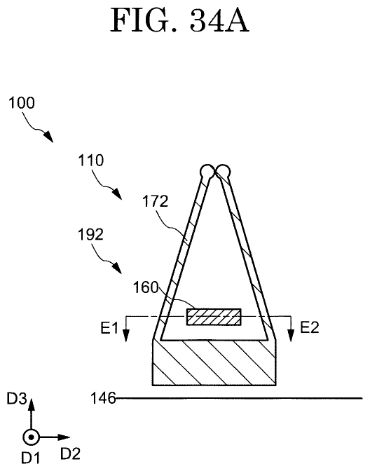

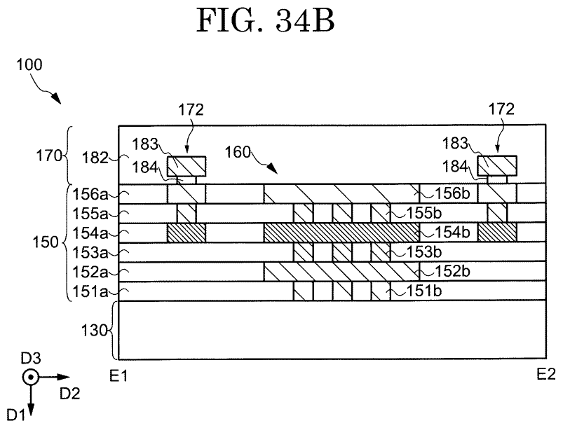

In the fifth embodiment, a seal ring 160 of the semiconductor module 10 will be described with reference to FIG. 32A to FIG. 34B. FIG. 32A is a plan view showing the configuration of the seal ring 160 and the inductor 172 included in the memory chip 110 according to the fifth embodiment of the present invention. FIG. 32B is a cross-sectional view showing a cross section of the seal ring 160 and the inductor 172 included in the memory chip 110 along a line C1-C2 of FIG. 32A. FIG. 33A is a plan view showing the configuration of a seal ring 260 and the inductor 272 included in the logic chip 200 according to the fifth embodiment of the present invention. FIG. 33B is a cross-sectional view showing a seal ring cross-section along a line J1-J2 of FIG. 33A. FIG. 34A is a plan view showing the configuration of the seal ring 260 and the inductor 172 included in the memory chip 110 according to the fifth embodiment of the present invention. FIG. 34B is a cross-sectional view showing a cross section of the seal ring 260 and the inductor 172 included in the memory chip 110 along a line E1-E2 of FIG. 34A. The description of the same or similar configurations as those in FIG. 1 to FIG. 31B will be omitted here.

As shown in FIG. 32A and FIG. 32B, the memory cube 100 includes the seal ring 160. The seal ring 160 is arranged on an outer periphery 192 and is formed in the wiring layer 150. The inductor 172 is formed to overlap (straddle) the seal ring 160. At least a portion of the inductor 172 is arranged outside the outer periphery 192. As described in “1-2. Overview of Memory Cube 100,” the wiring layer 150 includes the multi-layer wiring structure.

As shown in the cross-sectional view of FIG. 32B, for example, the wiring layer 150 includes a multi-layer wiring structure of six layers (first to sixth layers). The six-layer multi-layer wiring structure includes an insulating layer 151a, a wiring 151b, an insulating layer 152a, a wiring 152b, an insulating layer 153a, a wiring 153b, an insulating layer 154a, a wiring 154b, an insulating layer 155a, a wiring 155b, an insulating layer 156a, and a wiring 156b. The insulating layer 151a in the first layer is formed on the transistor layer 130, and the wiring 151b in the first layer is formed on the transistor layer 130 penetrating the insulating layer 151a. The insulating layer 152a in the second layer is formed on the insulating layer 151a and the wiring 151b, and the wiring 152b in the second layer is formed on the wiring 151b penetrating the insulating layer 152a. Similar to the first and second layers of the multi-layer wiring structure, the insulating layer 153a and the wiring 153b in the third layer, the insulating layer 154a and the wiring 154b in the fourth layer, the insulating layer 155a and the wiring 155b in the fifth layer, and the insulating layer 156a and the wiring 156b in the sixth layer are formed.

The inductor layer 170 is formed on the wiring layer 150. For example, the inductor layer 170 includes the insulating layer 182 and a wiring 183 forming the inductor 172.

The seal ring 160 has a function for suppressing moisture absorption, entry of impurities, and the like from the second side surface 146 of the memory cube 100. As a result, by using the seal ring 160, the semiconductor module 10 can suppress corrosion, deterioration, and the like of the inductor 172 caused by moisture absorption and intrusion of impurities and the like.

As shown in FIG. 33A and FIG. 33B, the logic chip 200 includes the seal ring 260. The seal ring 260 is arranged on an outer periphery 298 and is formed in the wiring layer 250. The inductor 272 is arranged inside the seal ring 260. As described in “1-3. Overview of Logic chip 200”, the wiring layer 250 includes the multi-layer wiring structure.

As shown in the cross-sectional view of FIG. 33B, for example, the wiring layer 250 includes a multi-layer wiring structure of six layers (first to sixth layers). The six-layer multi-layer wiring structure includes an insulating layer 251a, a wiring 251b, an insulating layer 252a, a wiring 252b, an insulating layer 253a, a wiring 253b, an insulating layer 254a, a wiring 254b, an insulating layer 255a, a wiring 255b, an insulating layer 256a, and a wiring 256b. Since the multi-layer wiring structure of the wiring layer 250 includes similar configurations and functions as the multi-layer wiring structure of the wiring layer 150, the description of the wiring layer 250 will be omitted here.

The inductor 172 may be formed using a plurality of wirings. For example, the inductor 172 is formed using five layers of wiring shown in FIG. 34A and FIG. 34B. Of the five layers of wiring forming the inductor 172, the wirings 154b, 155b, and 156b are formed of the same wiring as the multi-layer wiring in the fourth to sixth layers of the wiring layer 150, and a wiring 184 is formed in the inductor layer 170. The wirings 154b, 155b, 156b, 184, and 183 are formed in this order from the lower layer to the upper layer, and are electrically connected. Since the inductor 172 is formed using the plurality of wirings, the resistance value of the inductor 172 can be reduced.

The insulating layers 182, 156a, 155a, and 154a are formed in a region where the inductor 172 straddles the seal ring 160. For example, the insulating layers 182, 156a, 155a, and 154a are formed using an insulating material different from a low dielectric constant material (low-k material). For example, the insulating material forming the insulating layers 182, 156a, 155a, and 154a is SiO₂, SiCN, SIN, SiON, or the like.

### Sixth Embodiment

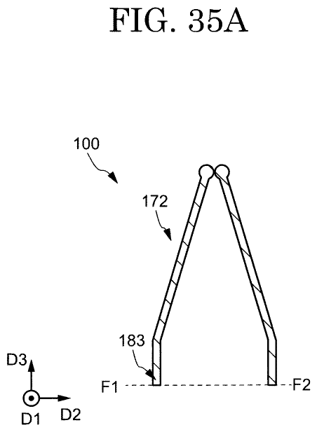

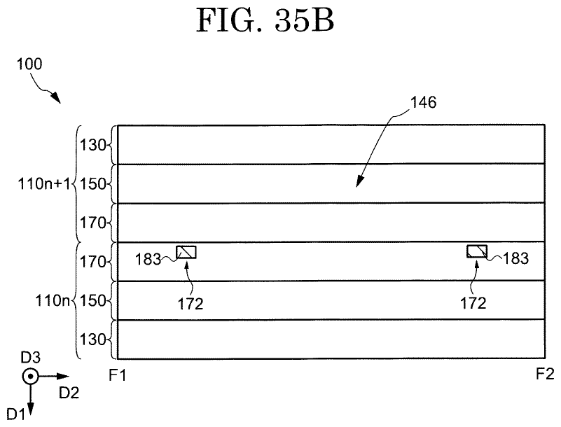

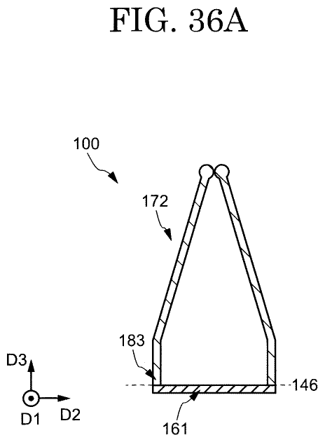

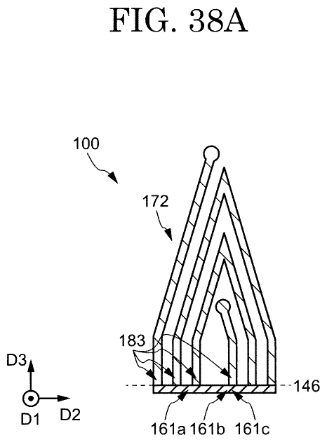

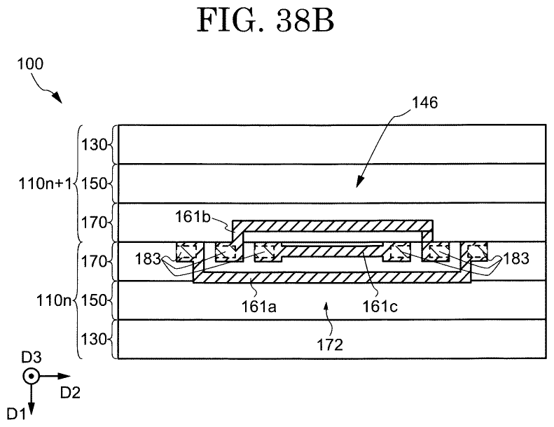

In the sixth embodiment, a method for forming the inductor 172 will be described with reference to FIG. 35A and FIG. 38B. In the method for forming the inductor 172 according to the sixth embodiment, two sides of the inductor 172 are formed in the memory cube 100, and one straight side of the inductor 172 is formed in the second side surface 146 of the memory cube 100. Since other configurations and functions are similar to those described in the first to second embodiments, the description will be omitted here.

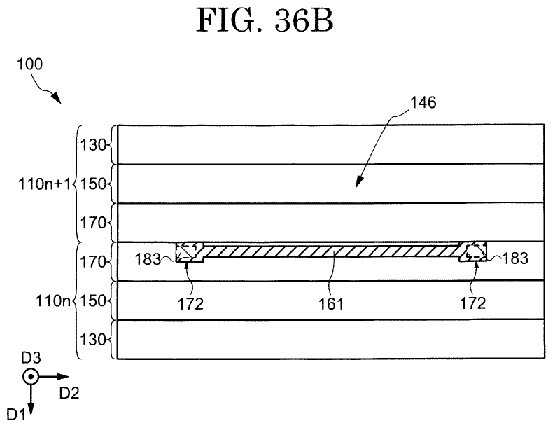

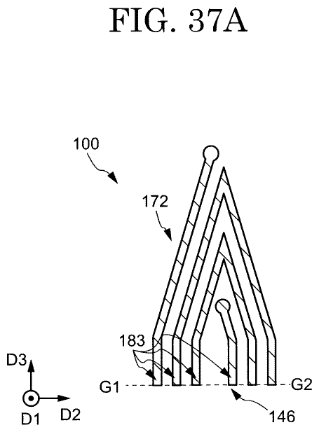

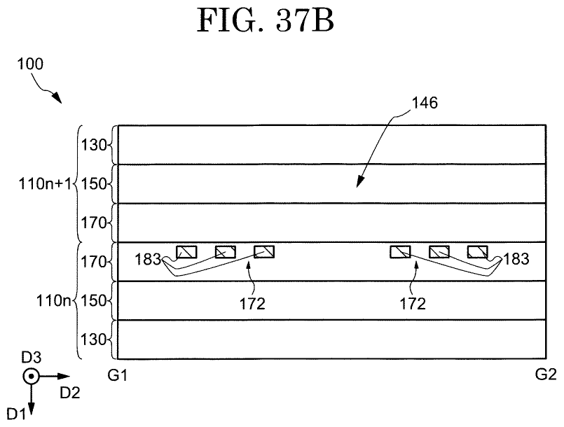

FIG. 35A and FIG. 36A are plan views showing a method for manufacturing a single-turn inductor 172 included in the memory cube 100 according to the sixth embodiment of the present invention. FIG. 35B is a side view showing an enlarged side view of the memory cube 100 and the single-turn inductor 172 included in the memory cube 100, and FIG. 36B is a cross-sectional view showing a cross-section of the memory cube 100 along a line F1-F2 of FIG. 35A. FIG. 37A and FIG. 38A are plan views showing a method for manufacturing a three-turn inductor included in the memory cube 100 according to the sixth embodiment of the present invention. FIG. 37B is a side view showing the memory cube 100 and an enlarged side view of the inductor 172 included in the memory cube 100, and FIG. 38B is a cross-sectional view showing a cross-section of the memory cube 100 along a line G1-G2 line of FIG. 37B. The description of the same or similar configurations as those in FIG. 1 to FIG. 34B will be omitted here.

As shown in FIG. 35A or FIG. 35B, the memory cube 100 includes the memory chips 110n and 110n+1. The memory chip 110n includes the inductor 172. In the method for forming the single-turn inductor 172 according to the sixth embodiment, in the process of forming the memory cube 100, the two sides of the inductor 172 of the memory chip 110n are formed using the wiring 183, and the wiring 183 forming the two sides of the inductor 172 is exposed to the second side surface 146.

As described in “1-5. Overview of Inductor Group 171 and Inductor Group 271”, since the inductor group 171 (the plurality of inductors 172) included in the memory chip 110n+1 is shifted from the position of the inductor group 171 (the plurality of inductors 172) included in the memory chip 110n, there is a region where the memory chip 110n includes the inductor 172 and the memory chip 110n+1 does not include the inductor 172 in a cross section in which the memory cube 100 is enlarged. In addition to the memory chip 110n, the inductor is formed in the same manner as the memory chip 110n in a region where the memory chip 110n+1 includes the inductor 172. Similar to the memory chip 110n+1 and 110n, the inductor 172 is formed in the other memory chip 110.

As shown in FIG. 36A or FIG. 36B, the memory cube 100 is formed using the wiring 183 to form two sides of the inductor 172 of the memory chip 110n, and then using a side surface wiring 161 to form one straight side. The side surface wiring 161 is formed on the second side surface 146 so as to overlap the wiring 183 forming the two sides exposed to the second side surface 146, and the side surface wiring 161 is electrically connected to the wiring 183 forming the two sides. The side surface wiring 161 around the wiring 183 has a wider wiring width so as to surround the wiring 183. This ensures that the side surface wiring 161 is connected to the wiring 183. In addition, the side surface wiring 161 of the wiring 183 may be referred to as an electrode pad and may be individually formed as the electrode pad.

As shown in the FIG. 37A to FIG. 38B, the memory cube 100 may include the three-turn inductor 172.

As shown in FIG. 37A to FIG. 37B, when the innermost turn is considered to be the first turn, the two sides constituting the first-turn inductor, the two sides constituting the second-turn inductor, and the two sides constituting the third-turn inductor are formed by the wiring 183. Therefore, the cross-sections of the six wirings 183 forming the two sides constituting the first-turn inductor, the two sides constituting the second-turn inductor, and the two sides constituting the third-turn inductor are exposed to the second side surface 146.

As shown in FIG. 38A or FIG. 38B, similar to forming the single-turn inductor 172, the memory cube 100 is formed on the second side surface 146 using the wiring 183 to form the two sides of each of the first to third turns of the inductor 172 of the memory chip 110n, and then using side surface wirings 161a to 161c to form one side of the single-turn straight line, one side of the two-turn straight line, and one side of the three-turn straight line. The side surface wiring 161c is formed on the second side surface 146 so as to overlap the wiring 183 forming the second side of the first turn exposed on the second side surface 146, and the side surface wiring 161c is electrically connected to the wiring 183 forming the second side of the first turn. Similar to the first turn, the side surface wiring 161b is electrically connected to the wiring 183 forming the second side of the second turn, and the side surface wiring 161a is electrically connected to the wiring 183 forming the second side of the third turn. Similar to forming the single-turn inductor 172, the side surface wirings 161a to 161c around the wiring 183 have a wider wiring width so as to surround the wiring 183.

The inductor 172 of the memory cube 100 according to the sixth embodiment is formed using the wiring 183 and the side surface wirings 161, 161a to 161c that are different from the wiring 183. The side surface wirings 161 and 161a to 161c are formed on the second side surface 146 of the memory cube 100. Therefore, by using the method for forming the inductor 172 according to the sixth embodiment, an interval (distance between the inductor 172 and the corresponding inductor 272 in a one-to-one manner) Dis can be shortened. As a result, the quality of the inductor communication between the inductor 172 and the inductor 272 can be improved.

### Seventh Embodiment

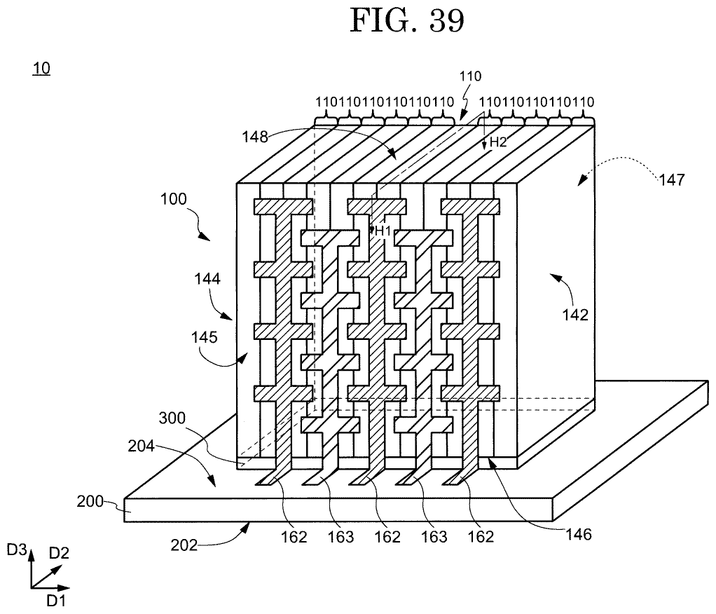

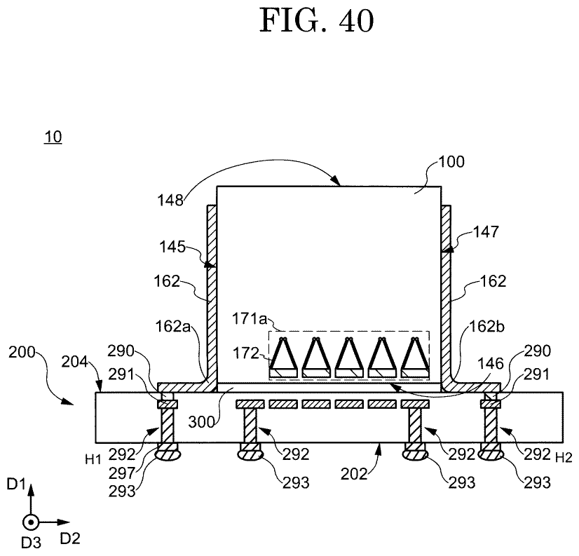

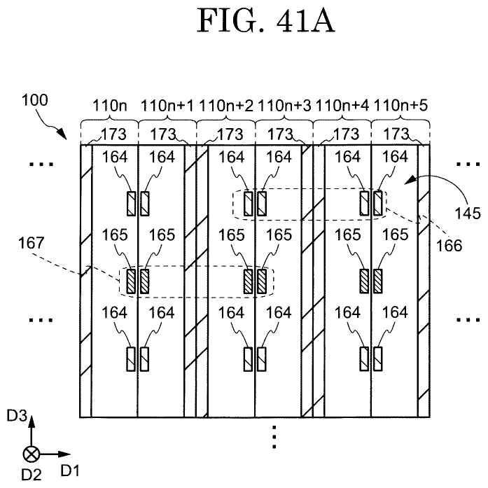

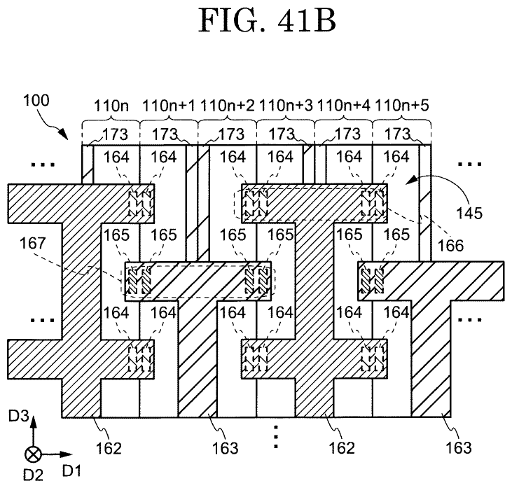

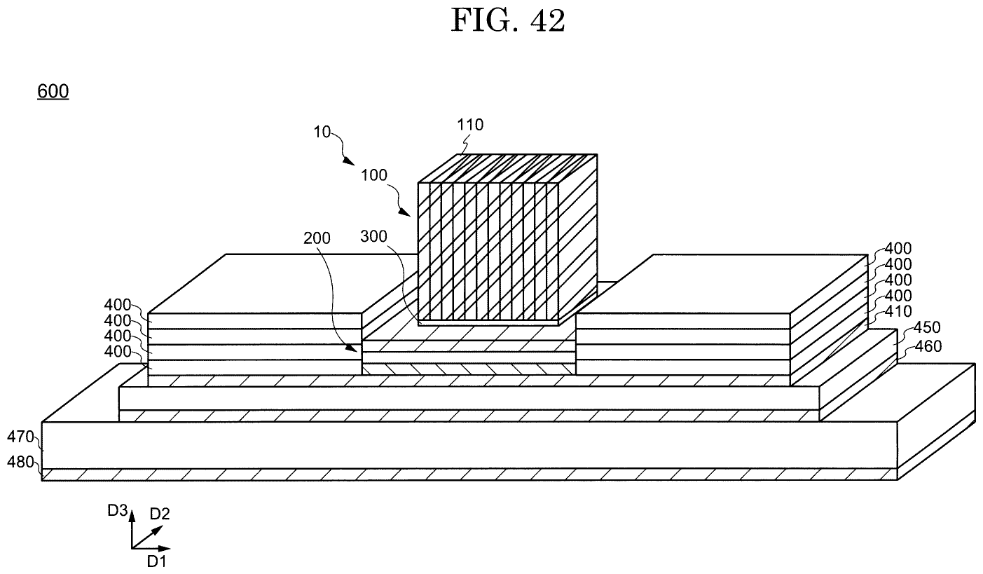

In the seventh embodiment, a power supply line and a ground line of the semiconductor module 10 will be described with reference to FIG. 39 to FIG. 41B. FIG. 39 is a perspective view showing a configuration of the power supply line and the ground line of the semiconductor module 10 according to the seventh embodiment of the present invention, FIG. 40 is a cross-sectional view showing a cross-section of the semiconductor module 10 along a line H1-H2 of FIG. 39, and FIG. 41A and FIG. 41B are side views showing a method for manufacturing the power supply line and the ground line of the semiconductor module 10 according to the seventh embodiment of the present invention. The description of the same or similar configurations as those in FIG. 1 to FIG. 38B will be omitted here.

As shown in FIG. 39, the semiconductor module 10 includes a plurality of side surface power supply wirings 162 and a plurality of side surface ground wirings 163. The plurality of side surface power supply wirings 162 and the plurality of side surface ground wirings 163 extend from at least over the first side surface 145 and the third side surface 147 of the memory cube 100 to over the second surface 204 of the logic chip 200, and are arranged on the first side surface 145 and the third side surface 147 of the memory cube 100 and on the second surface 204 of the logic chip 200. A portion of the plurality of side surface power supply wirings 162 and a portion of the plurality of side surface ground wirings 163 may be arranged on the adhesive layer 300.

As shown in the cross-sectional view of FIG. 40, the plurality of side surface power supply wirings 162 and the plurality of side surface ground wirings 163 are in contact with at least the first side surface 145 and the third side surface 147 of the memory cube 100 and the second surface 204 of the logic chip 200. In addition, the logic chip 200 includes a wiring 290, an electrode pad 291, a through electrode 292, an electrode pad 297, and a bump 293. The wiring 290 is electrically connected to the plurality of side surface power supply wirings 162, the plurality of side surface ground wirings 163, and the electrode pad 291. The electrode pad 291 is electrically connected to the through electrode 292. The through electrode 292 is exposed to the first surface 202 and is electrically connected to the electrode pad 297 formed on the first surface 202. The bump 293 is electrically connected to the electrode pad 297, and is electrically connected to an external circuit, a substrate, or the like. Power (VDD), VSS, and the like are supplied to the plurality of side surface power supply wirings 162 and the plurality of side surface ground wirings 163 via the wiring 290, the electrode pad 291, the through electrode 292, the electrode pad 297, and the bump 293. As a result, the power (VDD), VSS, and the like are supplied to the memory cube 100. In addition, the logic chip 200 includes a wiring formed in the same layer as the electrode pad 291, and the power (VDD), VSS, and the like are supplied to the respective circuits in the logic chip 200 using the electrode pad 291 and the wiring.

A method for manufacturing the power supply line and the ground line of the semiconductor module 10 will be described with reference to FIG. 41A and FIG. 41B. For example, the memory chips 110n to 110n+5 are bonded by F2F bonding and B2B bonding to form the memory cube 100. In addition, after the first side surface 145 to the fourth side surface 148 of the memory cube 100 are polished, the memory cube 100 is arranged on the logic chip 200 using the adhesive layer 300. As shown in FIG. 41A, a plurality of power supply wirings 164 and a plurality of ground wirings 165 are exposed to the first side surface 145 (third side surface 147) of the memory cube 100.

For example, the memory chip 110n, the memory chip 110n+1, the memory chip 110n+2, and the memory chip 110n+3 are bonded by F2F bonding, and the memory chip 110n+1 and the memory chip 110n+2 are bonded by B2B bonding. In the B2B bonding, the first surfaces 102 of the transistor layer 130 of the memory chip 110 on the substrate 173 side are bonded to each other.

As shown in FIG. 41A, the power supply wiring 164 of each of the memory chip 110n+2 to the memory chip 110n+5 is exposed to the first side surface 145. As shown in FIG. 41B, the plurality of side surface power supply wirings 162 and the plurality of side surface ground wirings 163 are formed in an L-shape on the second side surface 146. The power supply wiring 164 of each of the memory chip 110n+2 to the memory chip 110n+5 is a set of power supply wiring 166 (a first set of rows), and a plurality of sets of power supply wiring 166 extending in the direction D1 and exposed in parallel in the direction D3 are electrically connected to each other by the side surface power supply wiring 162. Similarly, the ground wiring 165 of each of the memory chip 110n to the memory chip 110n+3 is a set of ground wiring 167 (a second set of rows), and a plurality of sets of ground wiring 167 exposed in parallel in the direction D3 is electrically connected by the side surface ground wiring 163. The set of power supply wiring 166 (the first set of rows) and the set of ground wiring 167 (the second set of rows) are arranged in parallel in the direction D3.

Similarly, the third side surface 147 opposite the first side surface 145 includes the plurality of side surface power supply wirings 162 and the plurality of side surface ground wirings 163, the plurality of power supply wirings 164 is electrically connected to the plurality of side surface power supply wirings 162, and the plurality of side surface ground wirings 163 is electrically connected to the plurality of side surface ground wirings 163.

The plurality of side surface power supply wirings 162 and the plurality of side surface ground wirings 163 may be formed in the same layer on the first side surface 145 and the third side surface 147 of the memory cube 100 and the second surface 204 of the logic chip 200. That is, using the two side surface wirings formed in the same layer, two different voltages can be supplied to the memory cube 100 and the logic chip 200 simultaneously.

### Eighth Embodiment

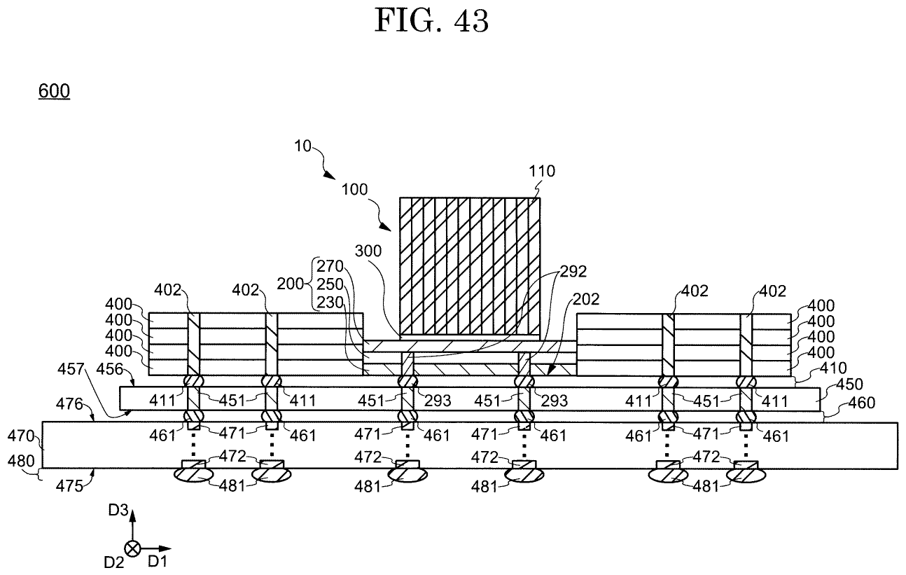

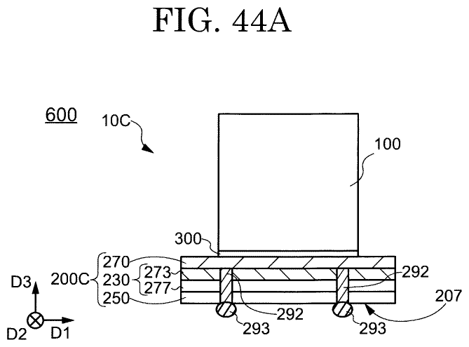

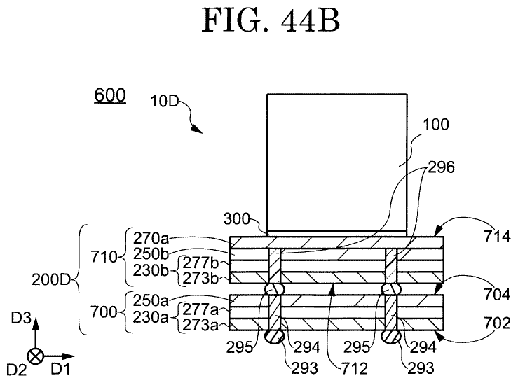

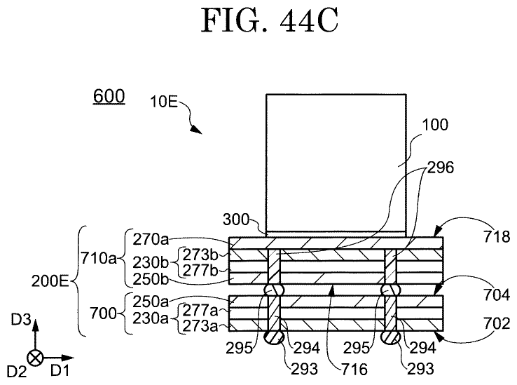

In the eighth embodiment, an integrated circuit 600 on which the semiconductor module 10 is mounted will be described with reference to FIG. 42 to FIG. 44C. FIG. 42 is a perspective view showing the integrated circuit 600 on which the semiconductor module 10 according to the eighth embodiment of the present invention is mounted, and FIG. 43 is a cross-sectional view showing a cross section of the integrated circuit 600 of FIG. 42. FIG. 44A to FIG. 44C are cross-sectional views showing a cross section of the integrated circuit 600 on which semiconductor modules 10C to 10E according to the eighth embodiment of the present invention are mounted. The description of the same or similar configurations as those in FIG. 1 to FIG. 41B will be omitted here.

As shown in FIG. 42 or FIG. 43, the integrated circuit 600 includes the semiconductor module 10, a plurality of DRAM modules 400, a bump layer 410, an interposer 450, a bump layer 460, a substrate 470, and a bump layer 480.

For example, each of the plurality of DRAM modules 400 stores a control program for controlling the plurality of memory chips 110 in the semiconductor module 10. For example, the DRAM module 400 may be a high-performance DRAM capable of wideband communication, referred to as HBM (High Bandwidth Memory (HBM).

The bump layer 410 includes a plurality of bumps 293 and a plurality of bumps 411, and includes a function for electrically connecting the semiconductor module 10, the DRAM module 400, and the interposer 450.

For example, the interposer 450 includes a second surface 456, a first surface 457, a plurality of wirings (wiring layer, not shown), and a plurality of through electrodes 451 extending from the second surface 456 to the first surface 457. The interposer 450 has a function for electrically connecting the semiconductor module 10 and the DRAM module 400 to the substrate 470. For example, the interposer 450 includes a function for electrically connecting the wiring included in the semiconductor module 10, the wiring included in the DRAM module 400, and the wiring included in the substrate 470 based on the positions of the respective wirings.

The bump layer 460 includes a plurality of bumps 461 and includes a function for electrically connecting the interposer 450 and the substrate 470.

For example, the substrate 470 includes a second surface 476, a first surface 475, and a plurality of wirings 471 and 472, and includes a function for connecting the semiconductor module 10, the plurality of DRAM modules 400, and the interposer 450 to an external substrate, external circuit, and the like. For example, the substrate 470 is a print substrate capable of high-density interconnection (High-density interconnect (HDI).

The bump layer 480 includes a plurality of bumps 481 and includes a function for connecting the substrate 470 to the external substrate, external circuit, and the like.

As shown in FIG. 43, the plurality of DRAM modules 400 is electrically connected by a through electrode 402. For example, the logic chip 200 includes a configuration in which the inductor layer 270, the wiring layer 250, and the transistor layer 230 are electrically connected using a plurality of through electrodes 292. The plurality of through electrodes 292 of the semiconductor module 10 is electrically connected to the through electrode 451 on the second surface 456 side in the interposer 450 using the plurality of bumps 293. For example, the plurality of DRAM modules 400 electrically connected by a plurality of through electrodes 402 is arranged on the left and right sides of the semiconductor module 10 in parallel in the direction D1, and is electrically connected to the through electrode 451 on the second surface 456 side of the interposer 450 using the plurality of bumps 411. The through electrode 451 on the first surface 457 side of the interposer 450 is electrically connected to the wiring 471 formed on the second surface 476 side of the substrate 470 using the plurality of bumps 461.

The integrated circuit 600 may have a configuration in which the semiconductor module 10 is replaced with the semiconductor module 10C shown in FIG. 44A. The semiconductor module 10C includes a logic chip 200C. In the logic chip 200C, the inductor layer 270 is formed on the substrate 273 side of the transistor layer 230. That is, the substrate 273 is arranged in a plane parallel to the direction D1 and the direction D2, and the transistor layer 230 and the wiring layer 250 above the transistor layer 230 are formed. The transistor layer 230 and the wiring layer 250 with respect to the direction D3 are turned upside down in the direction D3, and the inductor layer 270 is formed on the substrate 273 on the side of the transistor layer 230 opposite to the side on which the wiring layer 250 is formed. For example, the semiconductor module 10C includes a configuration in which the inductor layer 270, the wiring layer 250, and the transistor layer 230 are electrically connected using the plurality of through electrodes 292. The bump 293 is arranged on a first surface 207 where the wiring layer 250 is exposed, and the semiconductor module 10C is electrically connected to the interposer 450.

The integrated circuit 600 may have a configuration in which the semiconductor module 10 is replaced with the semiconductor module 10D shown in FIG. 44B. The semiconductor module 10D includes a logic chip 200D. The logic chip 200D includes a logic section 700 and a TCI-IO section 710.

The logic section 700 includes a transistor layer 230a and a wiring layer 250a. The transistor layer 230a includes at least a substrate 273a and an insulating layer 277a and has the same functions and configurations as the transistor layer 230. The wiring layer 250a includes functions and configurations similar to the wiring layer 250. For example, the logic section 700 includes the plurality of logic modules 211, the plurality of DRAMIOs 215, and the plurality of external IOs 216 shown in FIG. 11. The plurality of logic modules 211, the plurality of DRAMIOs 215, and the plurality of external IOs 216 are created using the transistor layers 230a and the wiring layer 250a.

The TCI-IO section 710 includes a transistor layer 230b, a wiring layer 250b, and an inductor layer 270a. The transistor layer 230b includes at least a substrate 273b and an insulating layer 277b and has similar functions and configurations as the transistor layer 230. The wiring layer 250a and the inductor layer 270a have similar functions and configurations as the wiring layer 250 and the inductor layer 270. For example, the TCI-IO section 710 includes the plurality of TCI-IOs 212 shown in FIG. 11, and the plurality of TCI-IOs 212 includes the plurality of inductors 272, a plurality of transmission/reception circuits 214, and a plurality of parallel-serial converting circuits 213. The plurality of inductors 272, the plurality of transmission/reception circuits 214, and the plurality of parallel-serial converting circuits 213 are created using the transistor layer 230b, the wiring layer 250b, and the inductor layer 270a.

In the TCI-IO section 710, the transistor layer 230b, the wiring layer 250b, and the inductor layer 270a layer are electrically connected using a through electrode 296. A second surface 714 of the TCI-IO section 710 on the inductor layer 270a side is connected to the adhesive layer 300 and is connected to the memory cube 100. A first surface 712 of the transistor layer 230b of the TCI-IO section 710 on the substrate 273b side is connected to a bump 295 and is electrically connected to the logic section 700.

In the logic section 700, the transistor layer 230a and the wiring layer 250a are electrically connected using a through electrode 294. A second surface 704 of the logic section 700 on the wiring layer 250a side is connected to the bump 295 and is electrically connected to the TCI-IO section 710. A first surface 702 of the transistor layer 230a of the logic section 700 on the substrate 273a side is connected to the bump 293 and is electrically connected to the interposer 450.

The integrated circuit 600 may have a configuration in which the semiconductor module 10 is replaced with the semiconductor module 10E shown in FIG. 44C. The semiconductor module 10E includes a logic chip 200E. The logic chip 200E includes the logic section 700 and a TCI-IO section 710a. The logic chip 200E replaces the TCI-IO section 710 with the TCI-IO section 710a with respect to the configuration of the logic chip 200D.

The TCI-IO section 710a includes a configuration in which the transistor layer 230b and the wiring layer 250b are turned upside down in the direction D3 with respect to the TCI-IO section 710. In the TCI-IO section 710a, the inductor layer 270a is formed on the substrate 273b side of the transistor layer 230b. That is, the substrate 273b is arranged in a plane parallel to the direction D1 and the direction D2, and the transistor layer 230b and the wiring layer 250b on the transistor layer 230b are formed. The formed transistor layer 230b and the wiring layer 250b are turned upside down in the direction D3, and the inductor layer 270a is formed on the substrate 273b opposite the side on which the wiring layer 250b is formed with respect to the transistor layer 230b. In the TCI-IO section 710a, the inductor layer 270a, the wiring layer 250b, and the transistor layer 230b are electrically connected using the plurality of through electrodes 296, and a second surface 718 on which the inductor layer 270a is exposed is connected to the adhesive layer 300 and is connected to the memory cube 100. A first surface 716, opposite the side on which the transistor layer 230b is formed with respect to the wiring layer 250b of the TCI-IO section 710a, is connected to the bump 295 and is electrically connected to the logic section 700.

### Ninth Embodiment

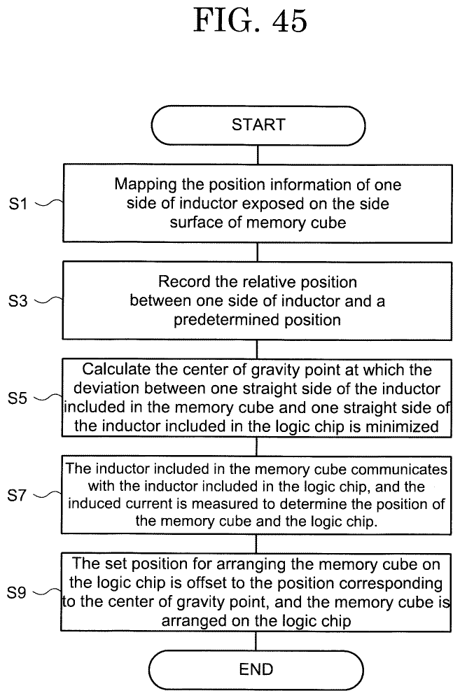

In the ninth embodiment, a method for mounting the semiconductor module 10 will be described with reference to FIG. 45. FIG. 45 is a flowchart showing a method for mounting a semiconductor module according to a ninth embodiment of the present invention. The description of the same or similar configurations as those in FIG. 1 to FIG. 44C will be omitted here.

As shown in FIG. 44, when the mounting of the semiconductor module 10 is started, in step 1 (S1), for example, the position information of one straight side 172ab of all the inductors 172 exposed on the second side surface 146 is mapped.

Next, in step 3 (S3), the relative position between the position information of the straight side 172ab of all the inductors 172 exposed on the second side surface 146 and a predetermined position of the second side surface 146 is recorded. For example, the predetermined position is four corners of the second side surface of the memory cube 100.

Next, in step 5 (S5), a center of gravity point at which the deviation between one straight side 172ab of all the inductors 172 exposed on the second side surface 146 and the inductor 272 on the logic chip 200, which corresponds one-to-one with respect to the respective inductors 172 is minimized is calculated.

Next, in step 7 (S7), the inductor 172 included in the memory cube 100 is made to communicate with the inductor 272 included in the logic chip 200. For example, the induced current of inductor 172 or inductor 272 is then measured. Furthermore, the memory cube 100 and the logic chip 200 are positioned based on the measured induced current.

Finally, in step 9 (S9), a set position (initial set position) for arranging the memory cube 100 on the second surface 204 of the logic chip 200 is offset to a position corresponding to the center of gravity point based on the calculated center of gravity point. Based on the offset set position, the memory cube 100 is arranged on the second surface 204 of the logic chip 200.

As described above, the semiconductor module 10 can be formed by arranging the memory cube 100 on the logic chip 200.

The semiconductor modules 10, 10A, 10B, 10C, 10D, and 10E exemplified as an embodiment of the present invention can be appropriately replaced without departing from the spirit of the present invention. In addition, various configurations of the semiconductor module and the method for manufacturing the semiconductor module exemplified as an embodiment of the present invention can be appropriately combined as long as no contradiction is caused, and the technical matters common to each embodiment are included in each embodiment without explicit description. Furthermore, the addition, deletion, or design change of components, or the addition, deletion, or condition change of processes as appropriate by those skilled in the art based on the semiconductor module and the method for manufacturing the semiconductor module disclosed in the specification and the drawings are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor module comprising:
a semiconductor chip including a first surface parallel to a first direction and a second direction intersecting the first direction, and a second surface parallel to the first surface; and
a memory cube including a plurality of memory chips stacked in the first direction and arranged on the second surface,
wherein
each of the plurality of memory chips includes a first inductor arranged in a third direction perpendicular to the first direction and the second direction,
the semiconductor chip includes a second inductor arranged parallel to the second surface,
the first inductor includes a first side and a second side extending in the third direction in a front view,
the distance between the first side and the second side cut parallel to the second surface becomes shorter as the distance from the second surface increases in the third direction, and
the first inductor and the second inductor are capable of contactless communication.

2. The semiconductor module according to claim 1, wherein
in a front view, the first inductor has a first portion including the first side extending in the third direction and including a finite first width in the second direction, a second portion including the second side extending in the third direction and including a finite second width in the second direction, and a third portion close to the second surface, including one straight side parallel to the second surface, extending in the second direction, including a length parallel to the second direction and including a finite third width in the third direction, and
the third width is wider than the first width and the second width.

3. The semiconductor module according to claim 2, wherein
in a plan view, the shape of a region formed by lines extending the first side and the second side in the third direction and the second direction, respectively, and a side extending one of the straight sides in the second direction, is triangular.

4. The semiconductor module according to claim 2,
wherein
the third width is different for each of the plurality of memory chips, and
the distance between one of the straight sides and the second surface is substantially the same.

5. The semiconductor module according to claim 1,
wherein
the memory chip includes a plurality of the first inductors,
the second inductor includes one straight side,
the one straight side of the first inductor and the one straight side of the second inductor are close to each other, and
the length parallel to the second direction is four times or more the distance between the one straight side of the first inductor and the one straight side of the second inductor.

6. The semiconductor module according to claim 1, wherein
the memory chip includes a plurality of the first inductors,
the second inductor includes one straight side,
the one straight side of the first inductor and the one straight side of the second inductor are adjacent to each other, and
the distance between the first inductor and another first inductor adjacent to the first inductor is equal to or greater than ¼ of the length parallel to the second direction.

7. The module device according to claim 1,
wherein
at least a portion of the first inductor is arranged outside a seal ring arranged on the outer periphery of the memory chip, and
the second inductor is arranged inside a seal ring arranged on the outer periphery of the semiconductor chip.

8. The module device according to claim 1,
wherein
the first inductor is composed of a wiring included in the memory chip and a side surface wiring arranged on a side surface of the memory cube, and
the wiring is different from the side surface wiring.

9. A semiconductor module comprising:
a memory cube including a plurality of stacked memory chips and including planarized first, second, third, and fourth side surfaces,
wherein
a wiring included in an inductor for communication is exposed on any one of the first, second, third, and fourth side surfaces,
a power supply wiring and a ground wiring are exposed on at least one of any of the other side surface, and
the wiring, the power supply wiring, and the ground wiring included in the inductor are included in wirings included in the memory chip.

10. The semiconductor module according to claim 9, further comprising
a semiconductor chip including a first side surface and a second side surface opposite the first side; and
a heat sink,
wherein
any one of the first, second, third, and fourth side surfaces is arranged to face the second side surface,
the heat sink is arranged on the side surface opposite any one side of the surfaces, and
at least one of the two side surfaces other than any one of the side surfaces and the opposite side surface is formed with a side surface power supply wiring electrically connected to the power supply wiring and a side surface ground wiring electrically connected to the ground wiring.

11. The semiconductor module according to claim 10,
wherein
the side surface power supply wiring and the side surface ground wiring are arranged to extend to the second surface of the semiconductor chip, and are connected to electrode pads included in the semiconductor chip.

12. The semiconductor module according to claim 10,
wherein
each of the plurality of memory chips includes a stacked configuration of a transistor layer including a substrate and a transistor and an inductor layer including the inductor, and
the memory cube includes a stacked configuration in which the inductor layers of any two of the plurality of memory chips are bonded to each other, the transistor layers of two of the plurality of memory chips other than the two memory chips are bonded to each other, and the plurality of memory chips is stacked.

13. The semiconductor module according to claim 9,
wherein
the memory cube includes a first memory chip, a second memory chip stacked on the first memory chip, a third memory chip stacked on the second memory chip, a fourth memory chip stacked on the third memory chip, a fifth memory chip stacked on the fourth memory chip, and a sixth memory chip stacked on the fifth memory chip,
the power supply wiring of each of the third memory chip to the sixth memory chip exposed on the at least one side surface is arranged as a first set of rows,
the first set of rows is electrically connected by the side surface power supply wiring formed on the at least one side surface,
the ground wiring of each of the first memory chip to the fourth memory chip exposed on the at least one side surface is arranged as a second set of rows,
the second set of rows is electrically connected by a side surface ground wiring formed on the at least one side surface, and
the first set of rows is parallel to the second set of rows.

14. The semiconductor module according to claim 12,
wherein
the side surface power supply wiring and the side surface ground wiring are arranged to extend from the side surface of the substrate to the second surface, and
the side surface power supply wiring and the side surface ground wiring include an L-shaped wiring that connects the memory cube and the semiconductor chip.

15. The semiconductor module according to claim 9, further comprising a side surface wiring electrically connected to a wiring included in the inductor,
wherein
the inductor includes the side surface wiring and a wiring included in the inductor.

16. The semiconductor module according to claim 9,
wherein
the memory cube includes a first memory chip, a second memory chip stacked on the first memory chip, a third memory chip stacked on the second memory chip, and a fourth memory chip stacked on the third memory chip,
the third memory chip is thinner than the first memory chip,
the second memory chip is thinner than the third memory chip, and
the fourth memory chip is thicker than the first memory chip.
